(19) United States
(12) Patent Application Publication
(10) Pub. No.: US 2026/0136518 A1
(43) Pub. Date: May 14, 2026

(54) METHOD OF MANUFACTURING SEMICONDUCTOR DEVICE AND VERTICALLY STACKED SEMICONDUCTOR DEVICE

(71) Applicant: INSTITUTE OF MICROELECTRONICS, CHINESE ACADEMY OF SCIENCES, Beijing (CN)

(72) Inventors: Huaxiang YIN, Beijing (CN); Qingzhu ZHANG, Beijing (CN); Lei CAO, Beijing (CN); Jiaxin YAO, Beijing (CN)

(21) Appl. No.: 19/172,898

(22) Filed: Apr. 8, 2025

(30) Foreign Application Priority Data
Nov. 12, 2024 (CN) 202411610448.5

(51) Int. Cl. H10B 10/00

(52) U.S. Cl. CPC H10B 10/125

(57) ABSTRACT

The present disclosure provides a method of manufacturing a semiconductor device and a vertically stacked semiconductor device. The method includes: arranging lower and upper field effect transistors on a substrate, an upper surface of the substrate is connected to lower surfaces of a lowest gate stack and a source/drain layer in the lower field effect transistor; forming a fully silicided layer on exposed lower surfaces of the gate stack and the source/drain layer in the lower field effect transistor; patterning the fully silicided layer to form an opening exposing the lower surface of the lowest gate stack in the lower field effect transistor and a silicided pattern connected to the lower surface of the source/drain layer in the lower field effect transistor; filling the opening with a dielectric material to serve as a lower isolation layer of the gate stack; arranging a contact hole connected to the silicided pattern.

### CROSS REFERENCE TO RELATED APPLICATION

This application claims priority to Chinese Patent Application No. 202411610448.5, filed on Nov. 12, 2024, the entire content of which is incorporated herein in its entirety by reference.

### TECHNICAL FIELD

The present disclosure relates to the field of semiconductor technology, and in particular, to a method of manufacturing a semiconductor device and a vertically stacked semiconductor device.

### BACKGROUND

With the continuous development of manufacturing process nodes and key technologies of integrated circuits, NS-GAA FET (Nano-Sheet Gate-All-Around Field-Effect Transistor) will replace the existing Fin FET (Fin Field-Effect Transistor) technology at nodes less than or equal to 3 nm. Furthermore, three-dimensional stacked transistors, which include three-dimensional stacked integrated transistors, VFET (Vertical Field-Effect Transistor) and the like, will become the main technology route after the 1 nm node. The three-dimensional stacked integrated transistor is 3DS FET, which is also known as CFET (Complementary Field Effect Transistor).

The main process methods for implementing 3DS FET include two categories, where one is sequential integration, and the other is self-aligned monolithic integration. The former process method is simple, but is limited by performance and resources; the latter process method enables high integration and superior performance, but is complex and has various process technology challenges.

### SUMMARY

The present disclosure provides a method of manufacturing a semiconductor device and a vertically stacked semiconductor device.

According to an aspect of the present disclosure, a method of manufacturing a semiconductor device is provided, including: arranging, on a substrate, a lower field effect transistor and an upper field effect transistor stacked in a vertical direction and an inter-device isolation layer between the lower field effect transistor and the upper field effect transistor, where each of the lower field effect transistor and the upper field effect transistor includes: a plurality of channel layers stacked with spacing between each other in the vertical direction; a source/drain layer connected to the plurality of channel layers on opposite sides of the channel layers in a first direction; and a gate stack that extends in a second direction intersecting the first direction and surrounds the channel layers; and where an upper surface of the substrate is connected to a lower surface of a lowest gate stack and a lower surface of the source/drain layer in the lower field effect transistor; etching the substrate to expose the lower surface of the lowest gate stack and the lower surface of the source/drain layer in the lower field effect transistor; forming a fully silicided layer on the exposed lower surface of the gate stack and the exposed lower surface of the source/drain layer in the lower field effect transistor; patterning the fully silicided layer so that the fully silicided layer at the lower surface of the lowest gate stack in the lower field effect transistor is removed, so as to form an opening exposing the lower surface of the lowest gate stack in the lower field effect transistor, and to form a silicided layer pattern connected to the lower surface of the source/drain layer in the lower field effect transistor on opposite sides of the opening in the first direction simultaneously; filling the opening with a dielectric material, so that the dielectric material filled in the opening serves as a lower isolation layer of the gate stack; and arranging a contact hole connected to the silicided layer pattern.

According to an embodiment of the present disclosure, the forming a fully silicided layer on the exposed lower surface of the gate stack and the exposed lower surface of the source/drain layer in the lower field effect transistor includes: inverting the lower field effect transistor and the upper field effect transistor, so that the exposed lower surface of the lowest gate stack and the exposed lower surface of the source/drain layer in the lower field effect transistor face upward; depositing a silicon layer on the exposed lower surface of the lowest gate stack and the exposed lower surface of the source/drain layer in the lower field effect transistor that face upward; and forming the fully silicided layer by means of a silicide reaction of a metal with the silicon layer.

According to an embodiment of the present disclosure, the metal includes at least one of Ti, Ni, Co, W, Pt, Al, Cu or Ru.

According to an embodiment of the present disclosure, the patterning the fully silicided layer includes: etching the fully silicided layer in the second direction according to a width of the gate stack surrounding the channel layers in the first direction, so as to form the opening and the silicided layer pattern arranged on the opposite sides of the opening.

According to an embodiment of the present disclosure, the method further includes: forming a dielectric layer surrounding the lower field effect transistor and the upper field effect transistor; etching the dielectric layer from top to form a source/drain layer opening exposing an upper surface of the source/drain layer of the upper field effect transistor, where a projection of the source/drain layer opening in the vertical direction protrudes, in the second direction, from a projection of the source/drain layer of the upper field effect transistor in the vertical direction; filling the source/drain layer opening with a conductive material; sealing the filled source/drain layer opening with a dielectric material; etching the dielectric layer from bottom according to a portion where the projection of the source/drain layer opening protrudes from the projection of the source/drain layer of the upper field effect transistor, so as to form an opening exposing a lower surface of the conductive material; and filling the opening exposing the lower surface of the conductive material with a conductive material, so as to form a contact hole connected to the source/drain layer of the upper field effect transistor.

According to an embodiment of the present disclosure, the contact hole is used to electrically connect the source/drain layer of the upper field effect transistor to a ground terminal; or the contact hole is used to electrically connect the source/drain layer of the upper field effect transistor to a bit line terminal.

According to an embodiment of the present disclosure, the arranging, on a substrate, a lower field effect transistor and an upper field effect transistor stacked in a vertical direction and an inter-device isolation layer between the lower field effect transistor and the upper field effect transistor includes: sequentially arranging a lower stack, an intermediate layer and an upper stack on the substrate, where each of the upper stack and the lower stack includes channel layers and sacrificial layers that are alternately arranged; patterning the lower stack, the intermediate layer, the upper stack and an upper portion of the substrate, so as to form a fin extending in the first direction; forming a sacrificial gate extending in the second direction and intersecting with the fin on the substrate; forming a gate spacer on a sidewall of the sacrificial gate; patterning the lower stack, the intermediate layer and the upper stack with the sacrificial gate and the gate spacer used as masks, so that each of the patterned lower stack, the patterned intermediate layer and the patterned upper stack includes a side surface exposed in the first direction; replacing the intermediate layer with the inter-device isolation layer; forming the source/drain layer of the lower field effect transistor connected to an exposed side surface of the channel layers in the lower stack, and forming the source/drain layer of the upper field effect transistor connected to an exposed side surface of the channel layers in the upper stack; and replacing the sacrificial gate and the sacrificial layers with the gate stack.

According to another aspect of the present disclosure, a vertically stacked semiconductor device is provided, including: a lower field effect transistor and an upper field effect transistor stacked in a vertical direction; an inter-device isolation layer between the lower field effect transistor and the upper field effect transistor; and fully silicided layers and a lower isolation layer that are alternately arranged on a lower surface of the lower field effect transistor, where each of the lower field effect transistor and the upper field effect transistor includes: a plurality of channel layers stacked with spacing between each other in the vertical direction; a source/drain layer connected to the plurality of channel layer on opposite sides of the channel layers in a first direction; and a gate stack that extends in a second direction intersecting the first direction and surrounds the channel layers; where a lower surface of a lowest gate stack in the lower field effect transistor is covered by the lower isolation layer; a lower surface of the source/drain layer of the lower field effect transistor is covered by an upper surface of a silicide pattern, and a lower surface of the silicide pattern is connected to a contact hole.

According to an embodiment of the present disclosure, the contact hole connected to the lower surface of the silicide pattern is electrically connected to a power supply terminal; and a contact hole connected to an upper surface of the source/drain layer of the upper field effect transistor extends downward from a side of the upper field effect transistor, so as to be electrically connected to a bit line terminal or a ground terminal from a backside of the vertically stacked semiconductor device.

According to an embodiment of the present disclosure, a thickness of the silicide pattern is in a range of 5 nm to 500 nm.

### BRIEF DESCRIPTION OF THE DRAWINGS

This application contains at least one drawing executed in color. Copies of this patent application with color drawings will be provided by the Office upon request and payment of the necessary fee.

The above and other objectives, features and advantages of the present disclosure will become clearer through the following description of embodiments of the present disclosure with reference to the accompanying drawings.

FIG. 1 schematically shows a schematic diagram of development of integrated circuits according to an embodiment of the present disclosure.

FIG. 2 schematically shows a schematic diagram of an evolution path of core transistor structures of integrated circuits according to an embodiment of the present disclosure.

FIG. 3 schematically shows a schematic diagram of a sequential integration process according to an embodiment of the present disclosure.

FIG. 4 schematically shows a schematic diagram of a self-aligned monolithic integration process according to an embodiment of the present disclosure.

FIG. 5 schematically shows a flowchart of a method of manufacturing a vertically stacked semiconductor device according to an embodiment of the present disclosure.

FIG. 6 schematically shows a schematic diagram of an SRAM integrated circuit according to an embodiment of the present disclosure.

FIG. 7 schematically shows a schematic diagram of a single-layer SRAM structure according to an embodiment of the present disclosure.

FIG. 8A schematically shows a schematic diagram of a layered structure of a vertically stacked semiconductor device according to an embodiment of the present disclosure.

FIG. 8B schematically shows a schematic diagram of a top structure in a vertically stacked semiconductor device according to an embodiment of the present disclosure.

FIG. 8C schematically shows a schematic diagram of a bottom structure in a vertically stacked semiconductor device according to an embodiment of the present disclosure.

FIG. 8D schematically shows a schematic diagram of a backside contact in a vertically stacked semiconductor device according to an embodiment of the present disclosure.

FIG. 9A schematically shows a schematic diagram of an axial direction of a vertically stacked semiconductor device extending along a first direction according to an embodiment of the present disclosure.

FIG. 9B schematically shows a schematic diagram of an axial direction of a vertically stacked semiconductor device extending along a second direction according to an embodiment of the present disclosure.

FIG. 10A to FIG. 10E schematically show schematic diagrams of various axial directions of a layered structure of a vertically stacked semiconductor device according to an embodiment of the present disclosure.

FIG. 11A to FIG. 49A, FIG. 11B to FIG. 49B, FIG. 41C, FIG. 41D, FIG. 48C, FIG. 48D, FIG. 49C and FIG. 49D schematically show schematic cross-sectional views of a vertically stacked semiconductor device along axial directions according to an embodiment of the present disclosure.

FIG. 46A′ to FIG. 49A′, FIG. 46B′ to FIG. 49B′, FIG. 48C′, FIG. 48D′, FIG. 49C′ and FIG. 49D′ schematically show schematic cross-sectional views of semiconductor devices along axial directions in related art.

FIG. 50 schematically shows a schematic structural diagram of a vertically stacked semiconductor device according to an embodiment of the present disclosure.

FIG. 51 schematically shows a schematic diagram of an SRAM structure implemented based on a vertically stacked semiconductor device according to an embodiment of the present disclosure.

### DETAILED DESCRIPTION OF EMBODIMENTS

Hereinafter, the embodiments of the present disclosure will be described with reference to the accompanying drawings. However, it should be understood that these descriptions are only exemplary and are not intended to limit the scope of the present disclosure. In the following detailed description, for the convenience of explanation, many specific details are set forth to provide a comprehensive understanding of the embodiments of the present disclosure. However, it is obvious that one or more embodiments may also be implemented without these specific details. In addition, in the following description, descriptions of well-known structures and technologies are omitted to avoid unnecessary confusion of the concepts of the present disclosure.

The terms used herein are only for describing specific embodiments and are not intended to limit the present disclosure. The terms “including”, “comprising”, etc. used herein indicate the presence of the features, steps, operations and/or components, but do not exclude the presence or addition of one or more other features, steps, operations or components.

All terms (including technical and scientific terms) used herein have the meanings commonly understood by those skilled in the art unless otherwise defined. It should be noted that the terms used herein should be interpreted as having a meaning consistent with the context of this specification and should not be interpreted in an idealized or overly rigid manner.

When using expressions such as “at least one of A, B, and C, etc.”, it should generally be interpreted according to the meaning of the expression generally understood by those skilled in the art (for example, “a system having at least one of A, B, and C” should include but is not limited to a system having A alone, B alone, C alone, A and B, A and C, B and C, and/or A, B, C, etc.).

In the embodiments of the present disclosure, the development of integrated circuits is demonstrated by taking the technology development route shown in FIG. 1 as an example. It should be noted that in FIG. 1, “Tech Node” refers to a semiconductor process node, which may be used to represent the critical size that is achievable using the process of integrated circuits. On this basis, referring to the technology development route shown in FIG. 1, it may be seen that the manufacturing processes for integrated circuits are sorted in descending order based on the size represented by the semiconductor process node, which are sequentially Planar 11A (i.e., planar transistor structure), Fin FET 11B, NS-GAA FET 11C, VFET 11D, and Stacked FET 11E. The sizes represented by Tech Node 12A corresponding to Planar 11A are sequentially 90, 65, 45, 32, 28 and 20 in descending order, in nm; the sizes represented by Tech Node 12B corresponding to Fin FET 11B are sequentially 14, 10, 7, 5 and 4 in descending order, in nm; the sizes represented by Tech Node 12C corresponding to NS-GAA FET 11C are sequentially 3 and 2 in descending order, in nm; the sizes represented by Tech Node 12D corresponding to VFET 11D and Stacked FET 11E are sequentially 1 and 0.7 in descending order, in nm.

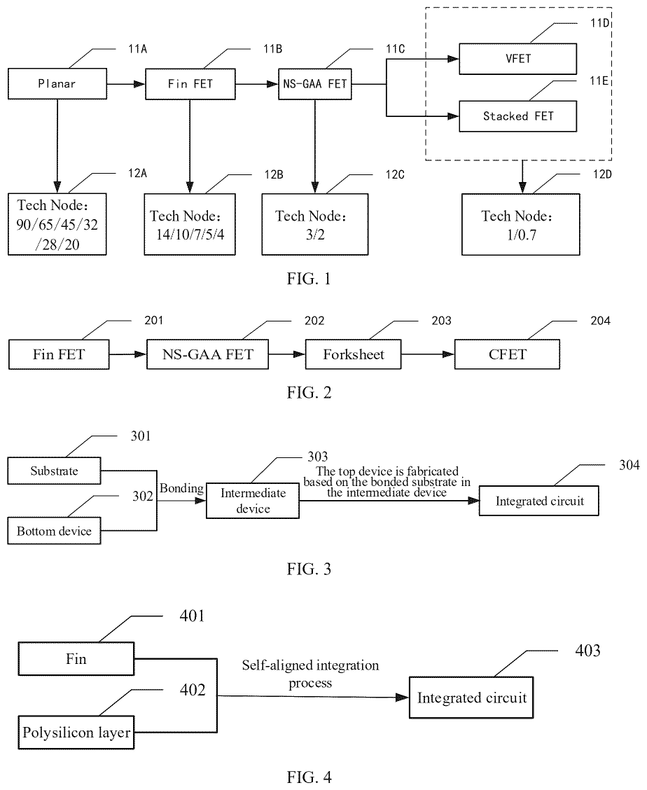

Further, as shown in FIG. 2, in the evolution path of the core transistor structure of integrated circuits, the core transistor structure develops from Fin FET 201 to NS-GAA FET 202, Forksheet 203, and further to the three-dimensional stacked integrated transistor within a single chip, namely 3DS FET or CFET (Complementary Field Effect Transistor) 204, so as to obtain higher integration density and overall performance.

As shown in FIG. 3 and FIG. 4, the main process methods for achieving 3DS FET include two categories: one is the sequential integration process (Sequential 3D), and the other is self-aligned monolithic integration process (Monolithic 3D). Taking two transistors stacked one above the other as an example, when the two transistors are manufactured using the sequential integration process, channel materials of the two transistors may be different from each other; when the two transistors are manufactured using the self-aligned monolithic integration process, the channel materials of the two transistors may be the same. For example, the sequential integration process may include: bonding a substrate 301 to an upper portion of a bottom device 302 to obtain an intermediate device 303; and manufacturing a top device based on the bonded substrate in the intermediate device, thereby obtaining an integrated circuit 304. The self-aligned monolithic integration process may include growing a polysilicon layer 402 surrounding multiple channel layers directly on a fin structure 401, and then processing it, so as to obtain an integrated circuit 403.

Therefore, the sequential integration process method is simple, but may be limited by performance and resources; the latter self-aligned monolithic integration process method has high integration and superior performance, but is complex and has various process technology challenges.

Specifically, advantages of the sequential integration process include: a flexible architecture design, an adjustable channel material as desired, a flexible arrangement of connections between transistors, etc. Disadvantages of the sequential integration process are mainly reflected in: high resource consumption, limitations of the manufacturing process, bonding, isolation space between N-P, thermal budget and lithography alignment.

Advantages of the self-aligned monolithic integration process include: low resource consumption, precise process control, such as self-aligned top and bottom devices, narrow isolation space between N-P, etc. Disadvantages of the self-aligned monolithic integration process are mainly reflected in: high process difficulty, such as processes with high aspect ratios, interconnections between devices, etc.

On this basis, the present disclosure provides a method of manufacturing a semiconductor device and a vertically stacked semiconductor device, so as to obtain a highly integrated CFET semiconductor device through a simple process. The method includes: arranging, on a substrate, a lower field effect transistor and an upper field effect transistor stacked in a vertical direction, and an inter-device isolation layer between the lower field effect transistor and the upper field effect transistor, where each of the lower field effect transistor and the upper field effect transistor includes: a plurality of channel layers stacked with spacing between each other in the vertical direction; a source/drain layer connected to the channel layers on opposite sides of the plurality of channel layers in a first direction; and a gate stack which extends in a second direction intersecting the first direction and surrounds the channel layers; and an upper surface of the substrate is connected to a lower surface of a lowest gate stack and a lower surface of the source/drain layer in the lower field effect transistor; etching the substrate to expose the lower surface of the lowest gate stack and the lower surface of the source/drain layer in the lower field effect transistor; forming a fully silicided layer on the exposed lower surface of the gate stack and the exposed lower surface of the source/drain layer in the lower field effect transistor; patterning the fully silicided layer so that the fully silicided layer at the lower surface of the lowest gate stack in the lower field effect transistor is removed, so as to form an opening exposing the lower surface of the lowest gate stack in the lower field effect transistor, and to form a silicided layer pattern that is connected to the lower surface of the source/drain layer in the lower field effect transistor on opposite sides of the opening in the first direction simultaneously; filling the opening with a dielectric material so that the dielectric material filled in the opening serve as a lower isolation layer of the gate stack; and arranging a contact hole connected to the silicided layer pattern.

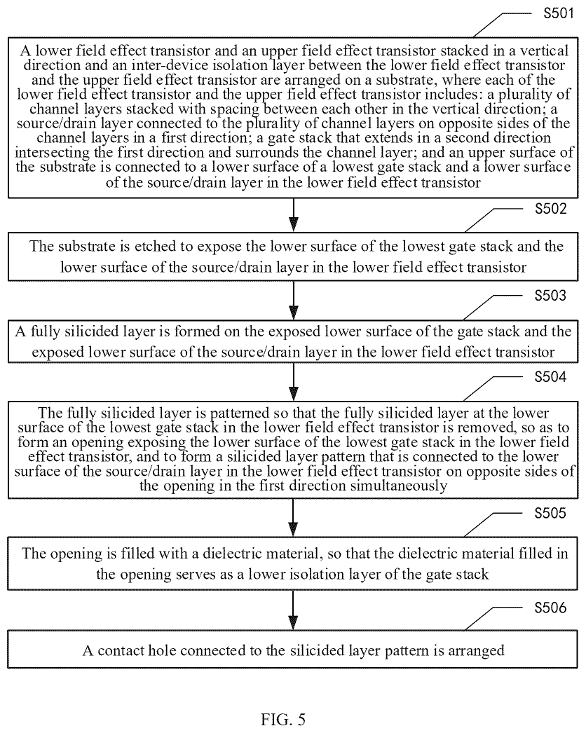

FIG. 5 schematically shows a schematic diagram of a method of manufacturing a semiconductor device according to an embodiment of the present disclosure.

As shown in FIG. 5, the method of manufacturing the semiconductor device in this embodiment includes operations S501 to S507.

In operation S501, a lower field effect transistor and an upper field effect transistor stacked in a vertical direction and an inter-device isolation layer between the lower field effect transistor and the upper field effect transistor are arranged on a substrate, where each of the lower field effect transistor and the upper field effect transistor includes: a plurality of channel layers stacked with spacing between each other in the vertical direction; a source/drain layer connected to the plurality of channel layers on opposite sides of the channel layers in a first direction; a gate stack that extends in a second direction intersecting the first direction and surrounds the channel layer; and an upper surface of the substrate is connected to a lower surface of a lowest gate stack and a lower surface of the source/drain layer in the lower field effect transistor.

In operation S502, the substrate is etched to expose the lower surface of the lowest gate stack and the lower surface of the source/drain layer in the lower field effect transistor.

In operation S503, a fully silicided layer is formed on the exposed lower surface of the gate stack and the exposed lower surface of the source/drain layer in the lower field effect transistor.

In operation S504, the fully silicided layer is patterned so that the fully silicided layer at the lower surface of the lowest gate stack in the lower field effect transistor is removed, so as to form an opening exposing the lower surface of the lowest gate stack in the lower field effect transistor, and to form a silicided layer pattern that is connected to the lower surface of the source/drain layer in the lower field effect transistor on opposite sides of the opening in the first direction simultaneously.

In operation S505, the opening is filled with a dielectric material, so that the dielectric material filled in the opening serves as a lower isolation layer of the gate stack.

In operation S506, a contact hole connected to the silicided layer pattern is arranged.

According to the embodiments of the present disclosure, the vertically stacked semiconductor device obtained using the manufacturing method of the present disclosure may be used to implement an SRAM structure (Static Random-Access Memory). For example, a first group of field effect transistors and a second group of field effect transistors that are arranged in the second direction and spaced apart from each other may be provided. The first group of field effect transistors and the second group of field effect transistors each include two vertically stacked semiconductor devices. Each vertically stacked semiconductor device may include vertically stacked field effect transistors. On this basis, the above-mentioned SRAM structure may be implemented based on the two sets of stacked field effect transistors in the first group of field effect transistors and two sets of stacked field effect transistors in the second group of field effect transistors.

The following takes the implementation of the SRAM structure as an example to explain the method of manufacturing the vertical semiconductor device of the embodiments of the present disclosure. It should be understood that the SRAM structure here is only an example, and those skilled in the art may implement other integrated circuit structures based on the vertical semiconductor device in the embodiments of the present disclosure as desired.

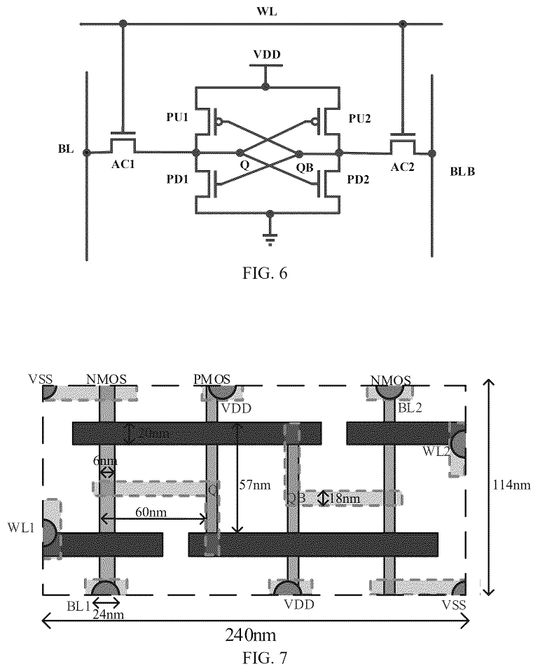

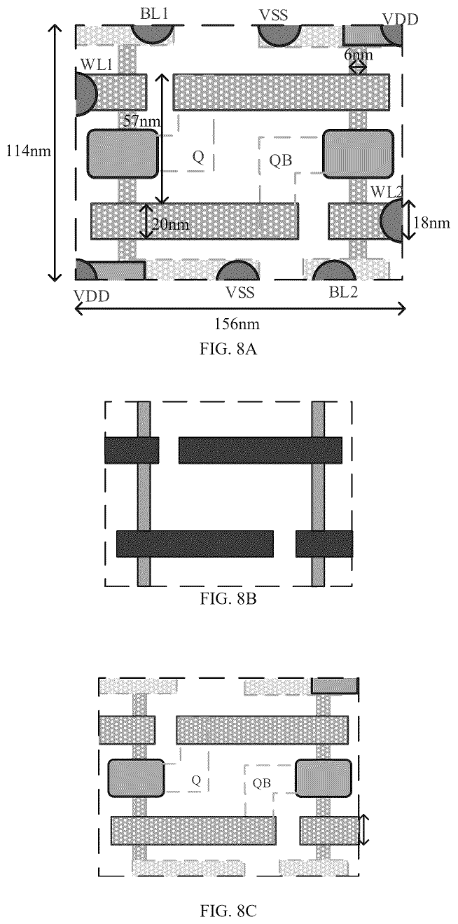

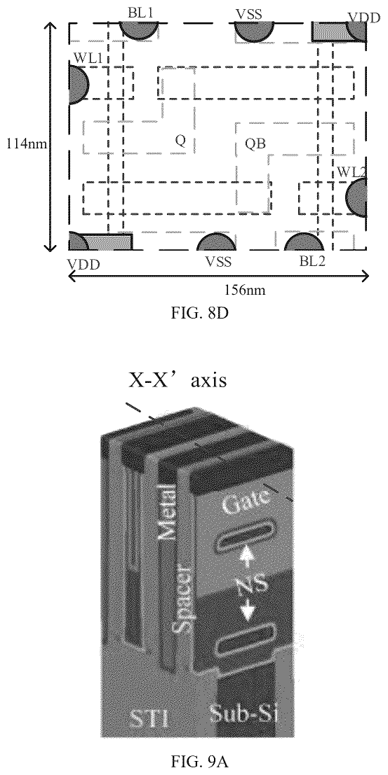

As shown in FIG. 6, SRAM is the core unit circuit of integrated circuits, and continuously reducing the SRAM cell area is the main theme of integrated circuit development. Transistors (3DS-FET or CFET) with three-dimensional stacked structures may be used to greatly reduce the SRAM cell area by more than 30%. Referring to FIG. 7 and FIG. 8A, by comparing the single-layer SRAM structure of FIG. 7 and the double-layer SRAM structure in FIG. 8A, it may be known that an area of the three-dimensional stacked structure (corresponding to the vertically stacked semiconductor device in the present disclosure) implemented in FIG. 8A is less than an area of the two-dimensional structure in FIG. 7. Further, the three-dimensional stacked structure in FIG. 8A may be divided into a top structure, a bottom structure, and a back contact pad. The top structure may be implemented based on NMOS, and the bottom structure may be implemented based on PMOS. On this basis, FIG. 8B shows the bottom structure of the three-dimensional stacked structure in FIG. 8A. FIG. 8C shows the top structure of the three-dimensional stacked structure in FIG. 8A. FIG. 8D shows the back contact pad of the three-dimensional stacked structure in FIG. 8A. It should be noted that the dimensions marked in the drawings of the present disclosure are examples and are not intended to limit the actual dimensions of the vertically stacked semiconductor devices in the present disclosure.

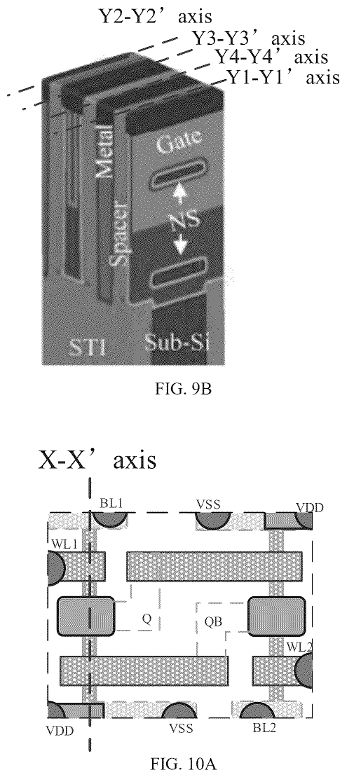

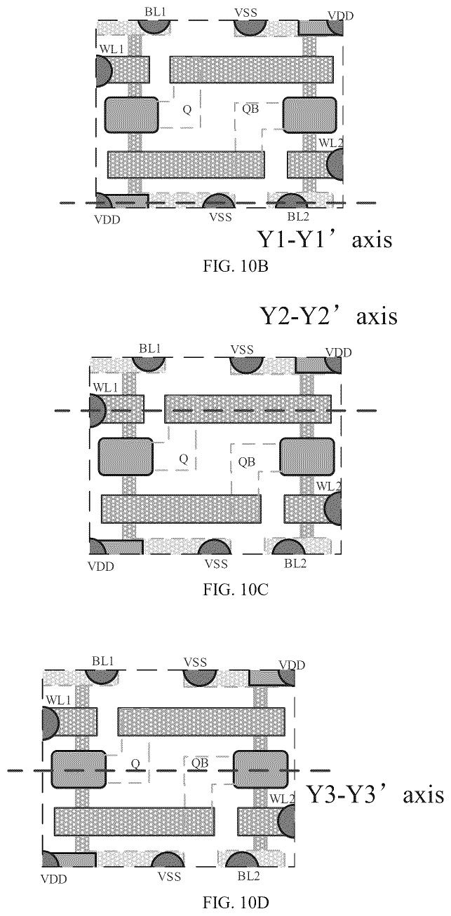

Taking SRAM as an example, various axial directions of the vertically stacked semiconductor device defined in the embodiments of the present disclosure are shown in FIG. 9A and FIG. 9B. FIG. 10A to FIG. 10E schematically show various axial directions of a layered structure of a vertically stacked semiconductor device used to implement SRAM in FIG. 8A. Here, the X-X′ axial direction extends along the first direction. The Y1-Y1′ axial direction, the Y2-Y2′ axial direction, the Y3-Y3′ axial direction and the Y4-Y4′ axial direction all extend along the second direction.

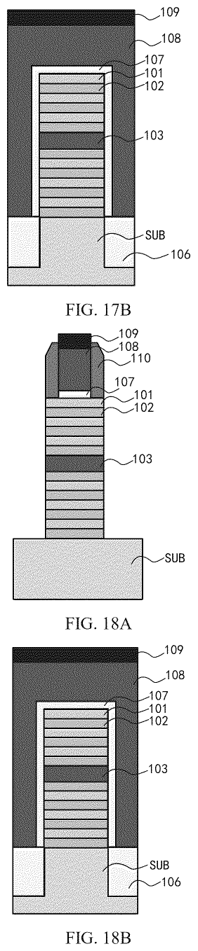

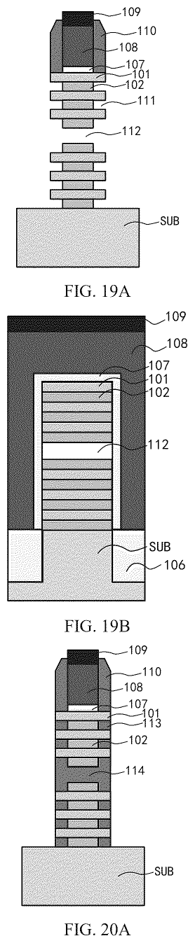

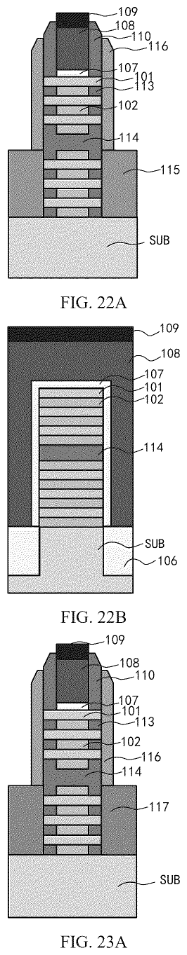

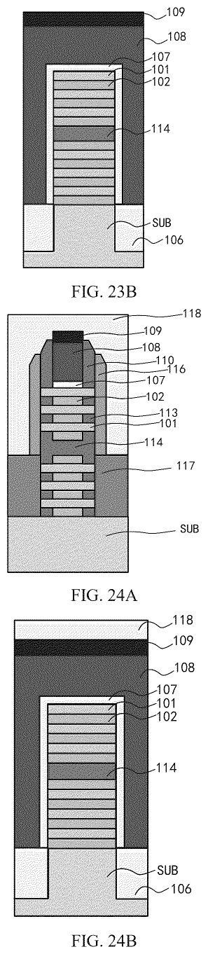

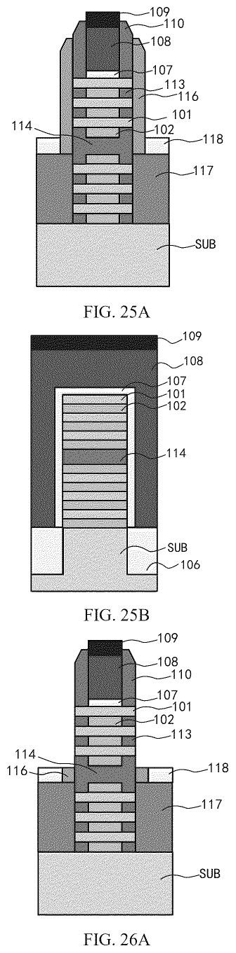

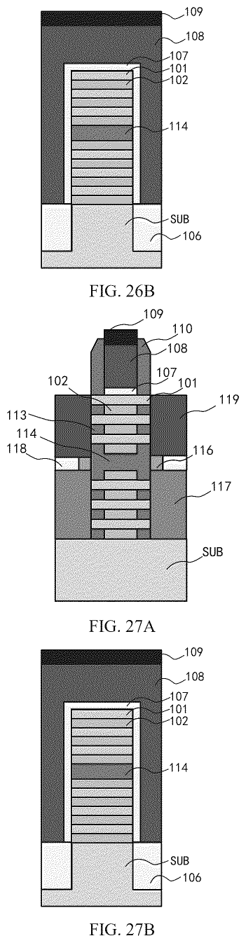

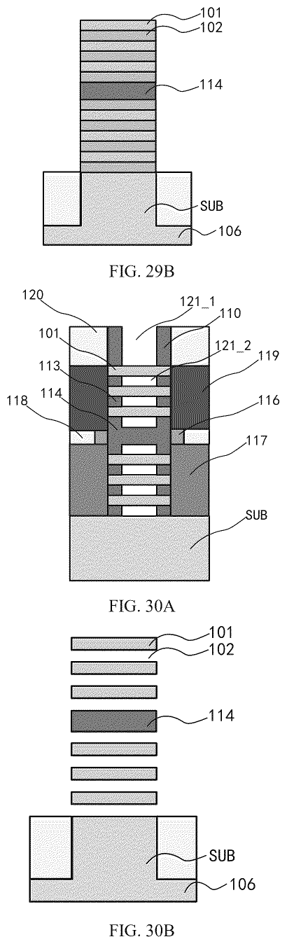

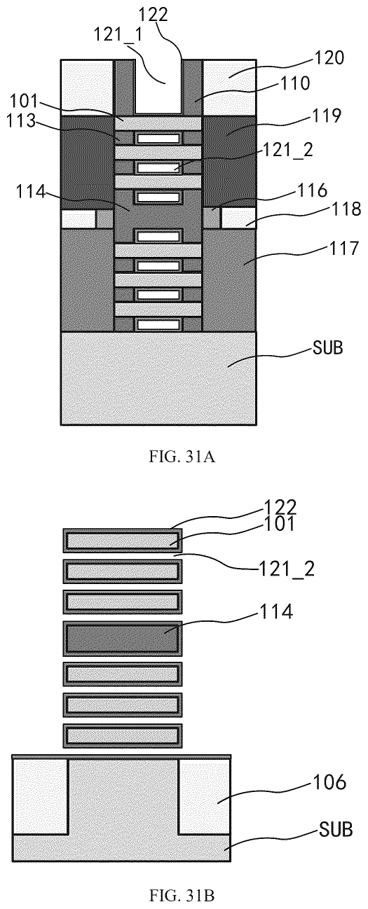

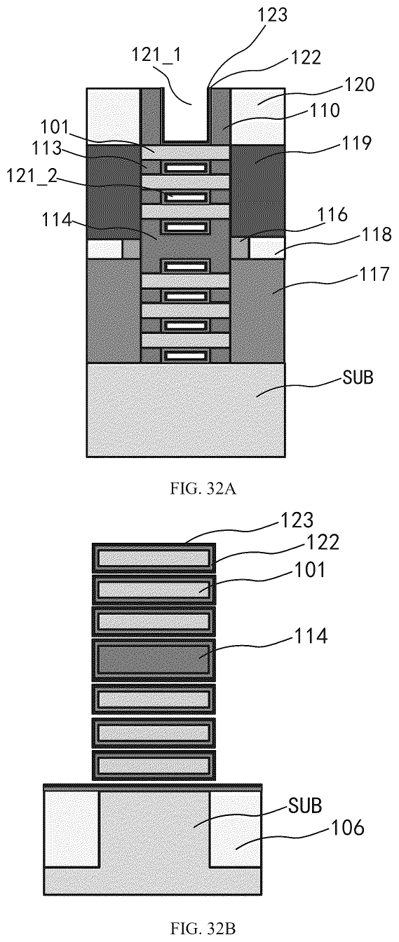

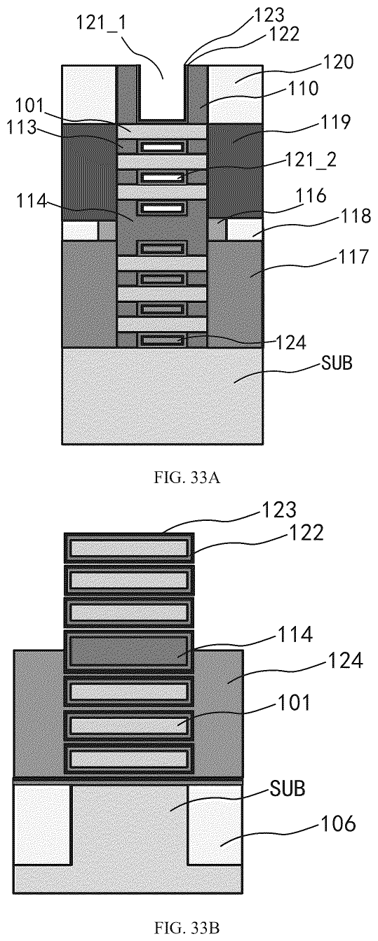

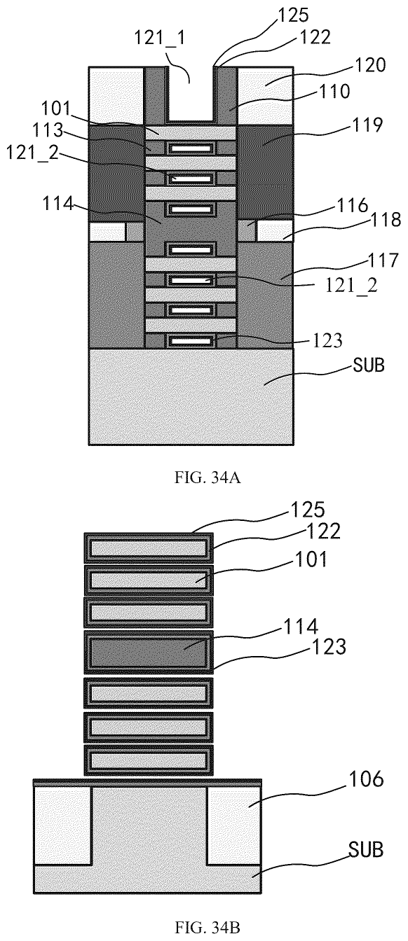

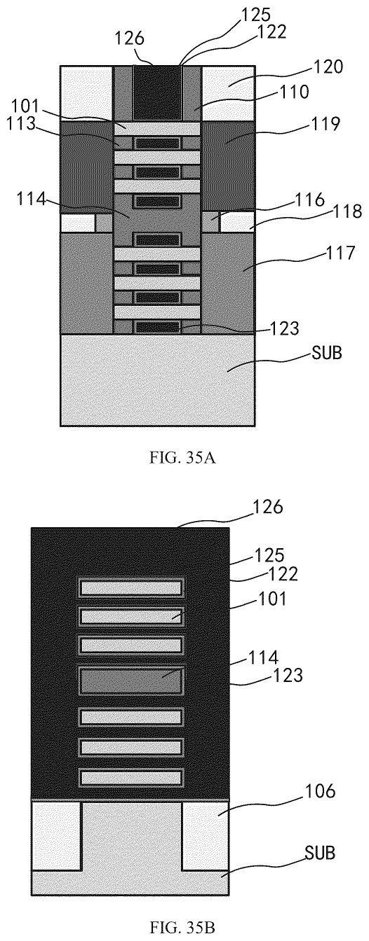

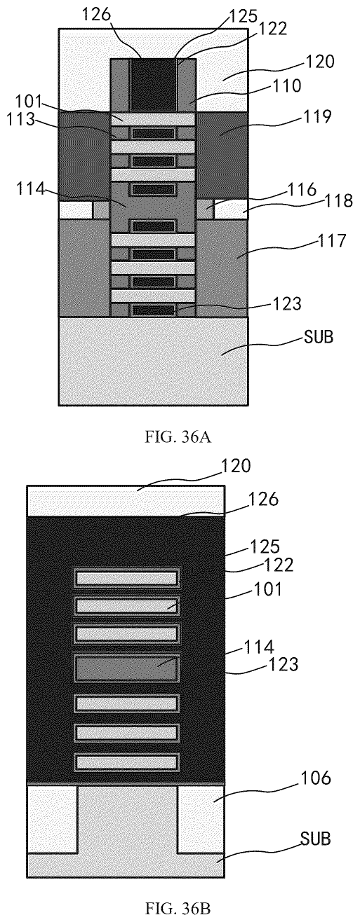

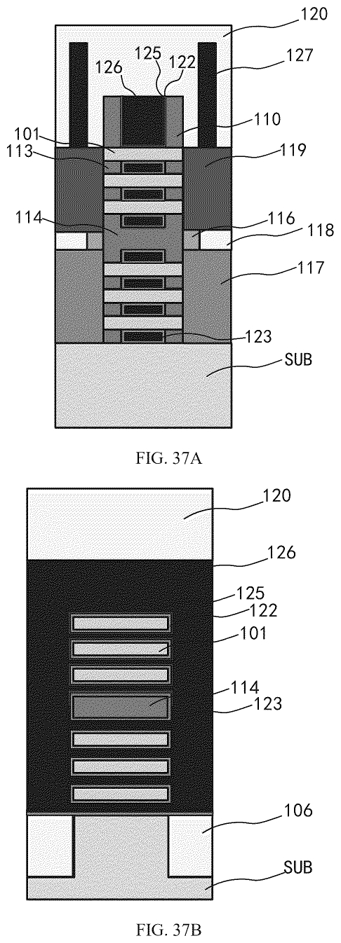

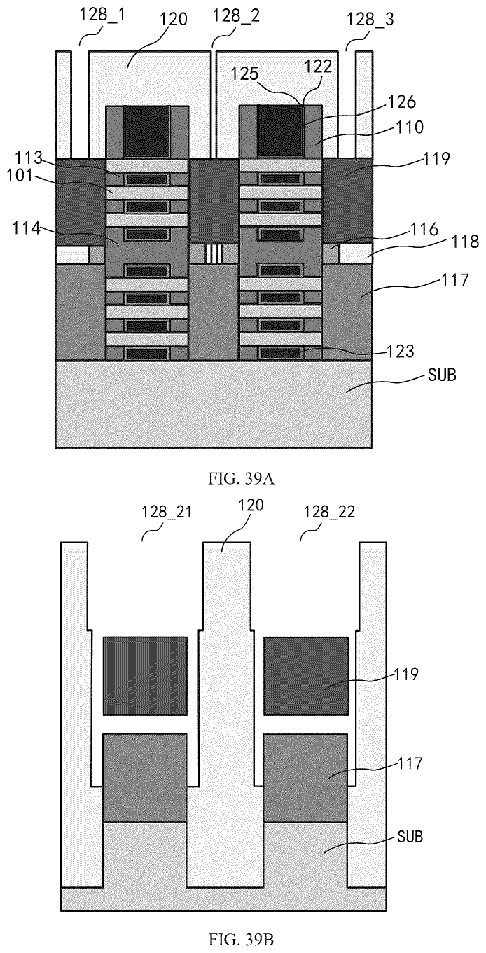

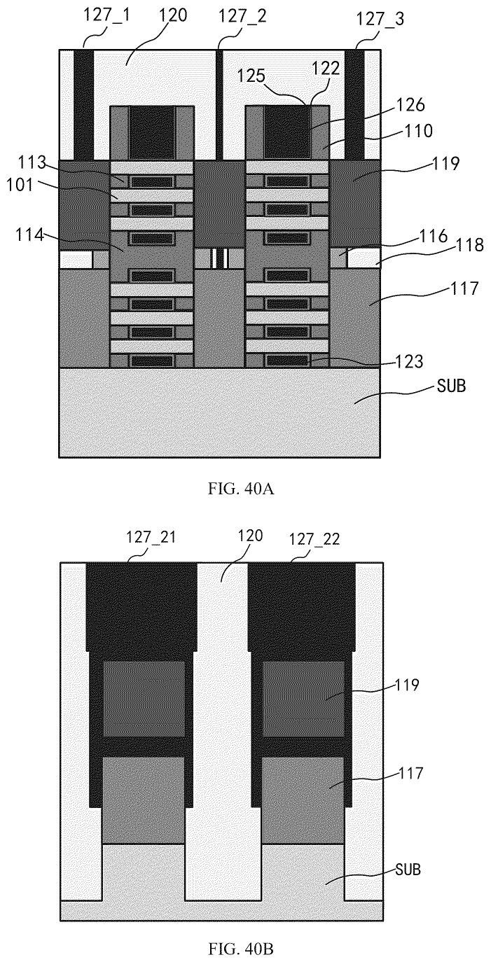

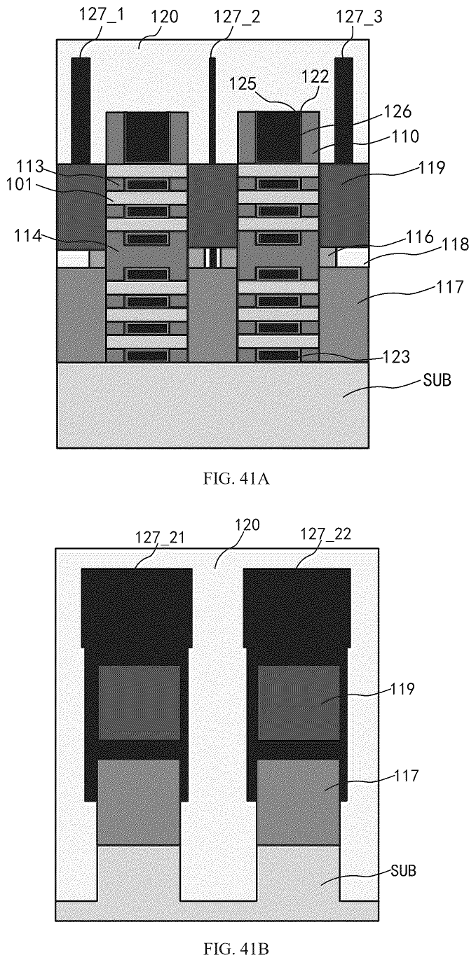

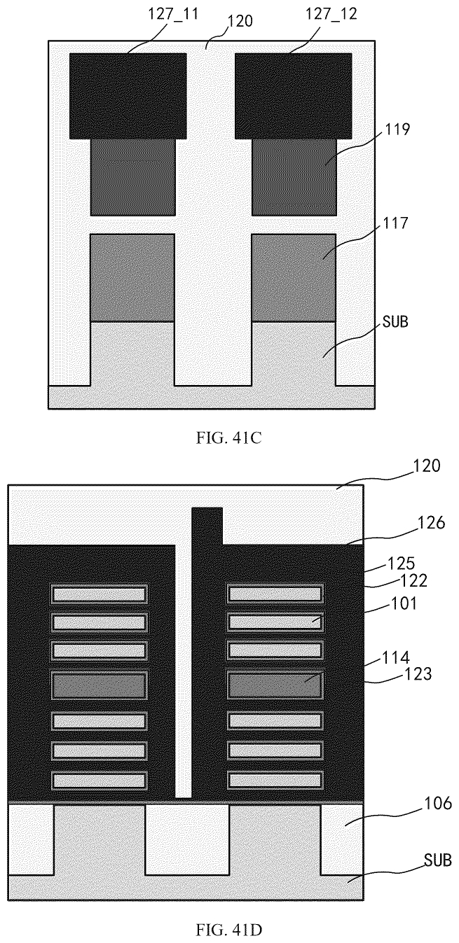

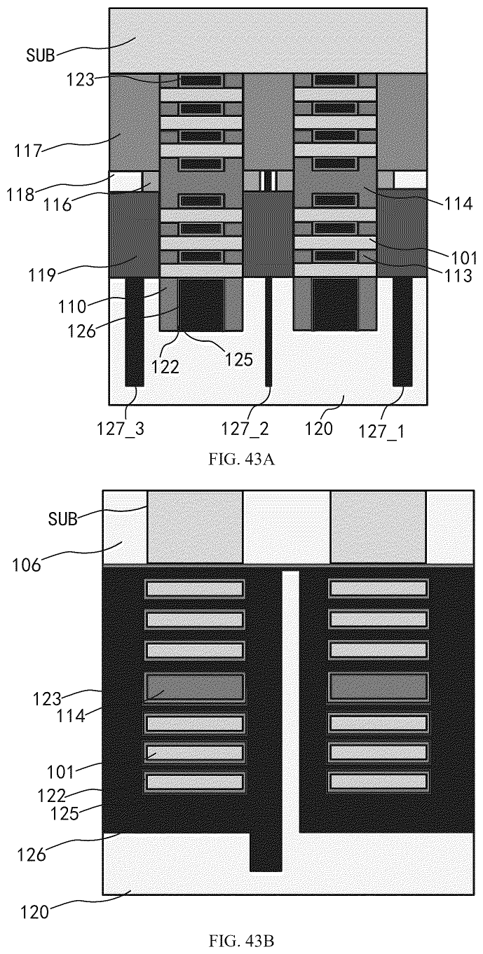

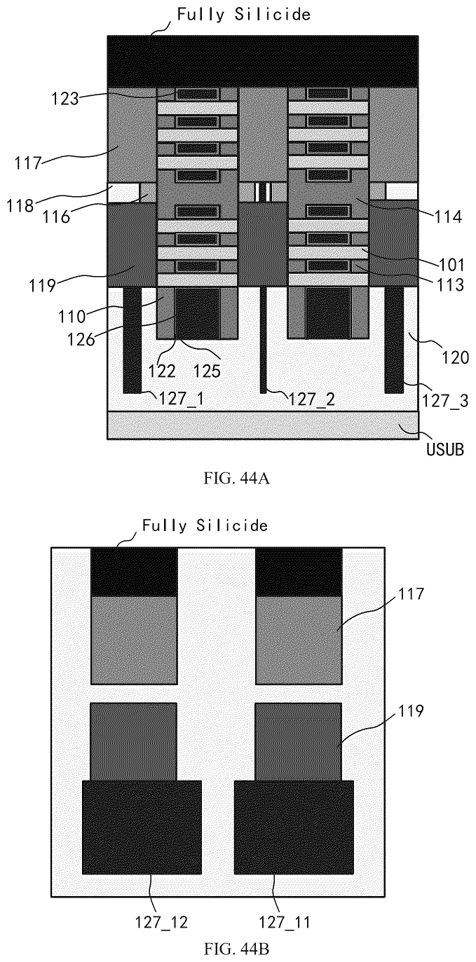

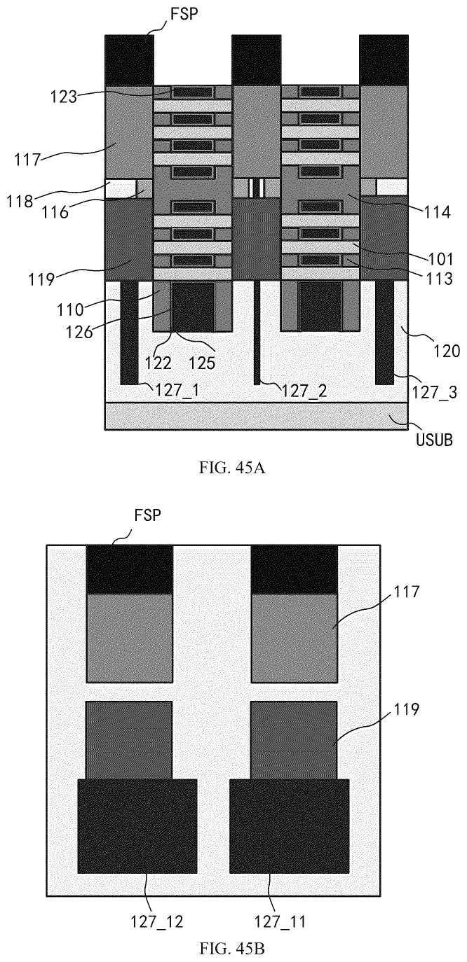

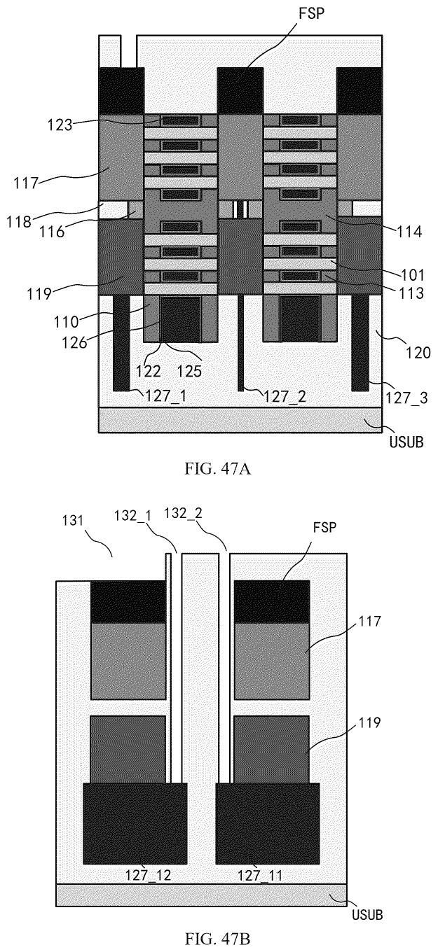

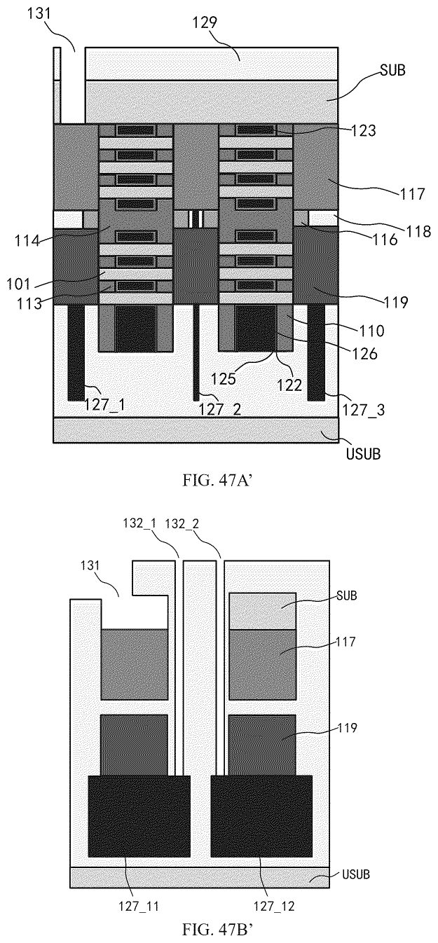

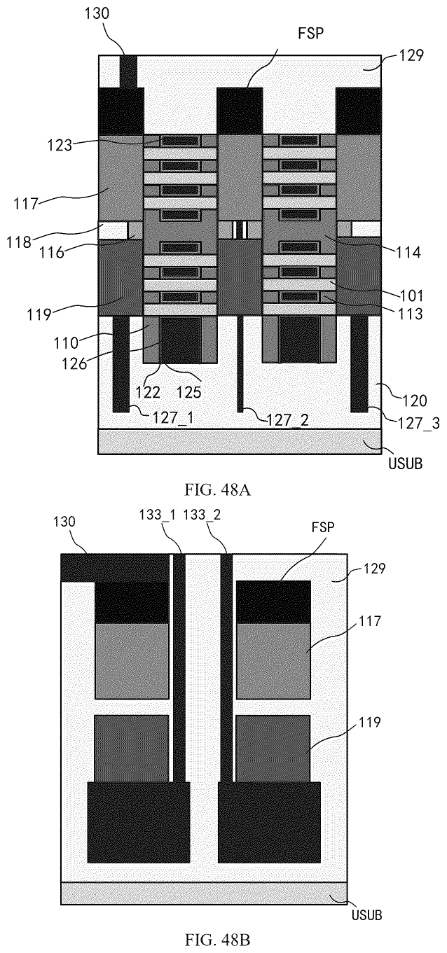

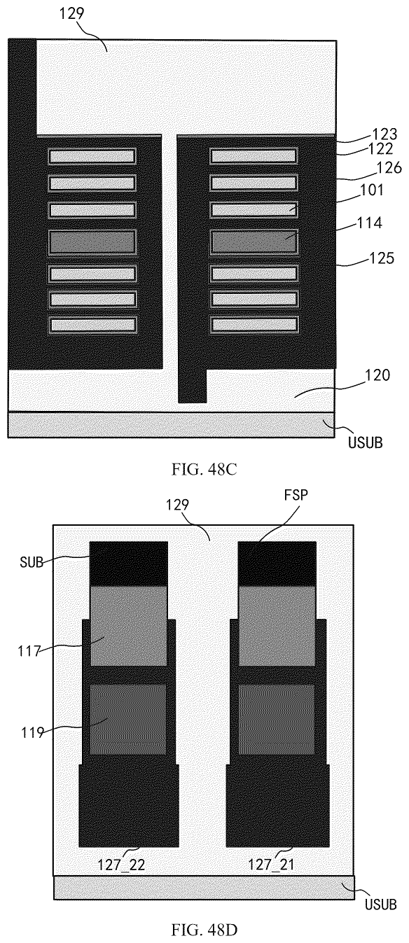

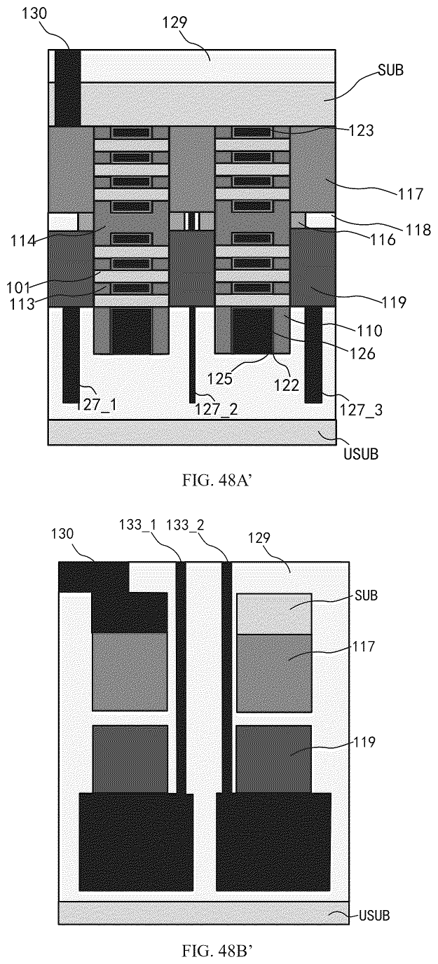

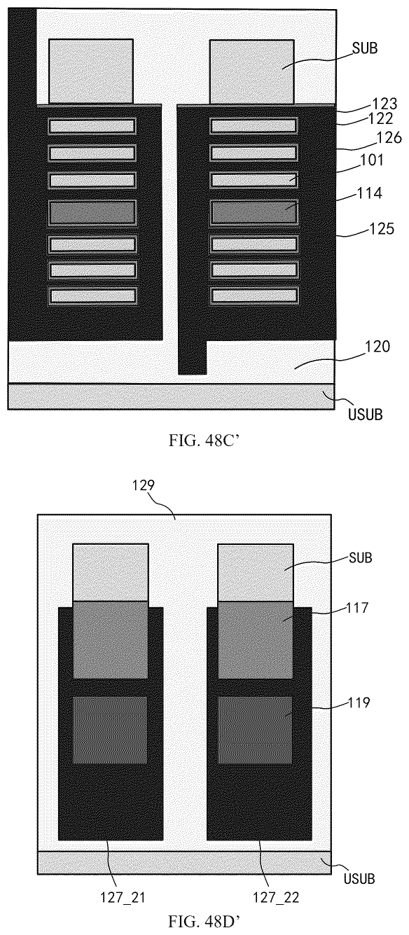

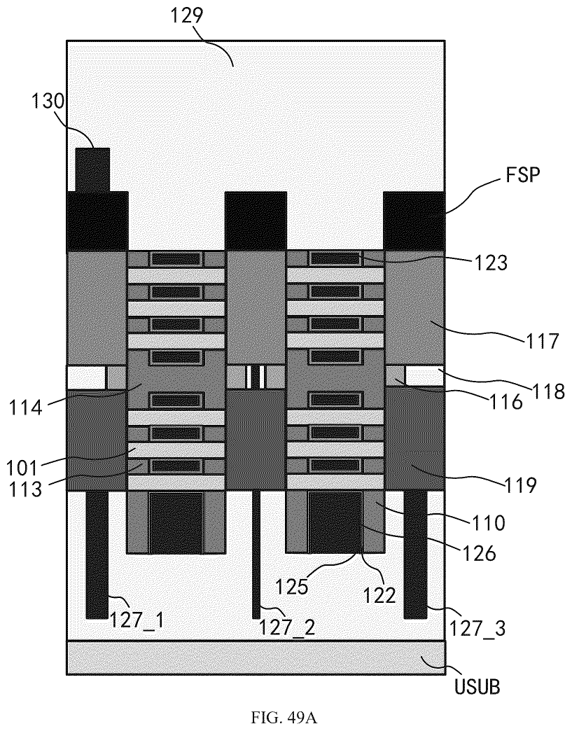

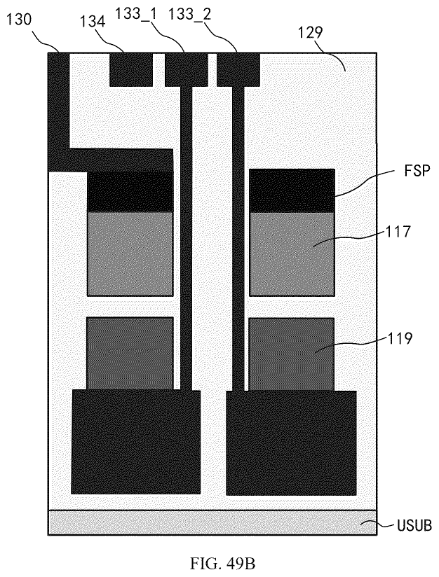

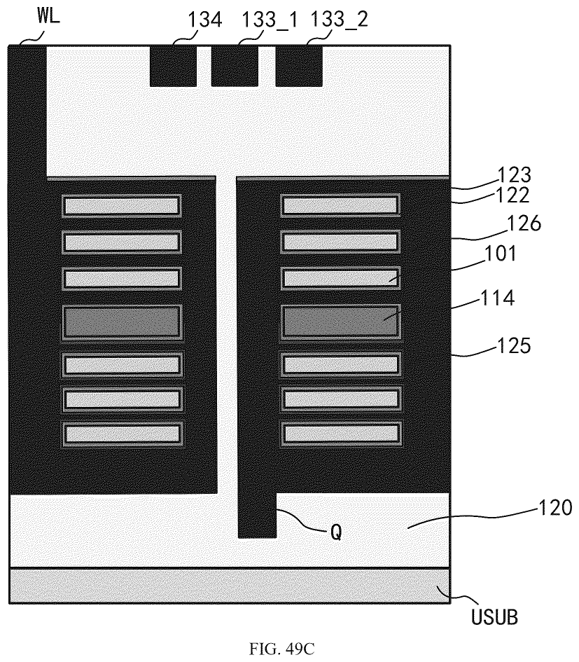

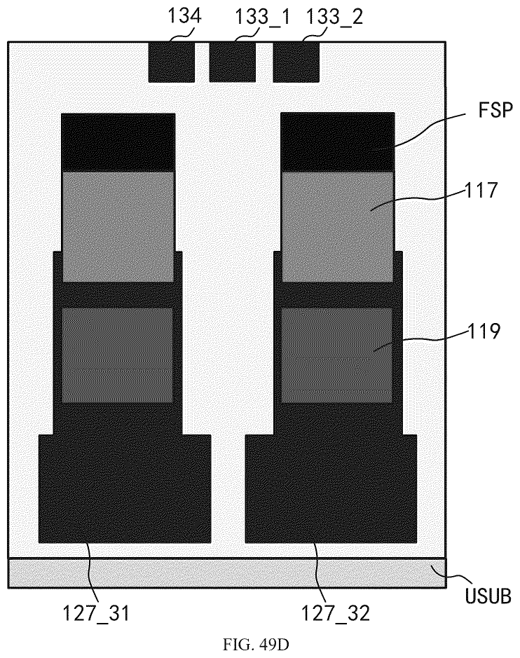

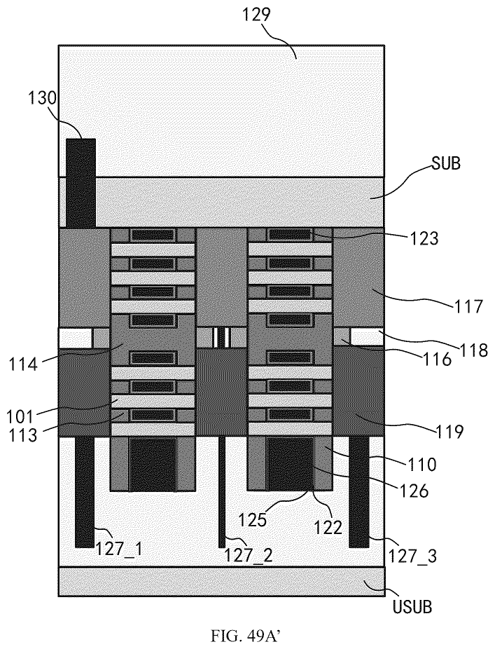

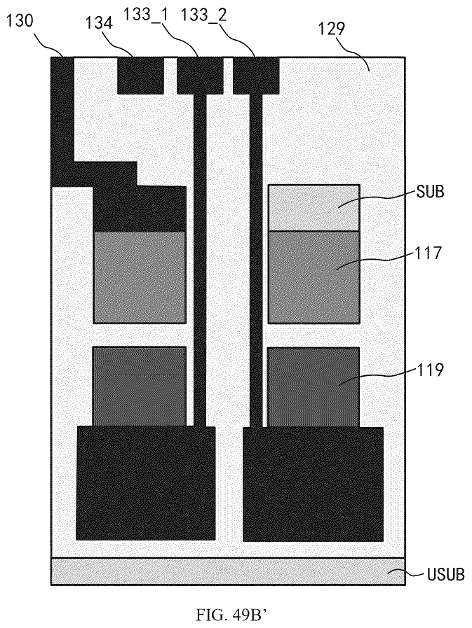

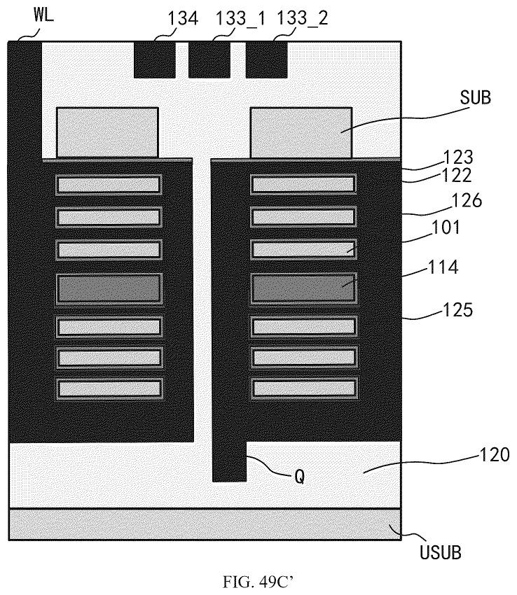

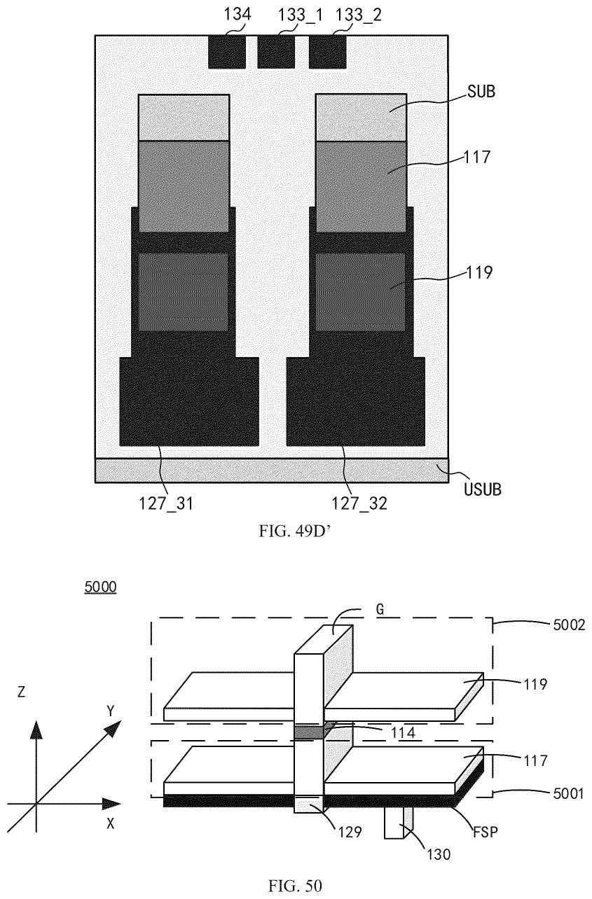

The following explains the contents of the embodiments of the present disclosure based on the cross-sectional views along the respective axial directions, namely, FIG. 11A to FIG. 49A, FIG. 11B to FIG. 49B, FIG. 41C, FIG. 41D, FIG. 48C, FIG. 48D, FIG. 49C and FIG. 49D, in the process of manufacturing a vertically stacked semiconductor device. It should be noted that in FIGS. 11A to 49A, 11B to 49B, 41C, 41D, 48C, 48D, 49C and 49D shown in the present disclosure, when the numbers in the figure numbers of multiple drawings are the same, the manufacturing processes corresponding to the multiple drawings are the same. When multiple drawings have the same figure number but different letters, the multiple drawings correspond to the same manufacturing process but different axial directions. For example, FIG. 11A and FIG. 11B are respectively cross-sectional views along two axial directions in the same manufacturing process.

According to the embodiments of the present disclosure, a lower field effect transistor and an upper field effect transistor stacked in a vertical direction and an inter-device isolation layer 114 between the lower field effect transistor and the upper field effect transistor are arranged on a substrate SUB, including the following steps. A lower stack, an intermediate layer 103 and an upper stack are sequentially arranged on the substrate SUB, where each of the upper stack and the lower stack includes channel layers 101 and sacrificial layers 102 that are alternately arranged. The lower stack, the intermediate layer, the upper stack and an upper portion of the substrate SUB are patterned, so as to form a fin extending in the first direction. A sacrificial gate extending in the second direction and intersecting with the fin is formed on the substrate. A gate spacer 110 is formed on a sidewall of the sacrificial gate. The lower stack, the intermediate layer 103 and the upper stack are patterned with the sacrificial gate and the gate spacer 110 used as masks, so that side surfaces of the patterned lower stack, the patterned intermediate layer 103 and the patterned upper stack are exposed in the first direction. The intermediate layer 103 is replaced with the inter-device isolation layer 114. A source/drain layer 117 of the lower field effect transistor connected to an exposed side surface of the channel layers 101 in the lower stack is formed, and a source/drain layer 119 of the upper field effect transistor connected to an exposed side surface of the channel layers 101 in the upper stack is formed. The sacrificial gate and the sacrificial layer 102 are replaced with a gate stack.

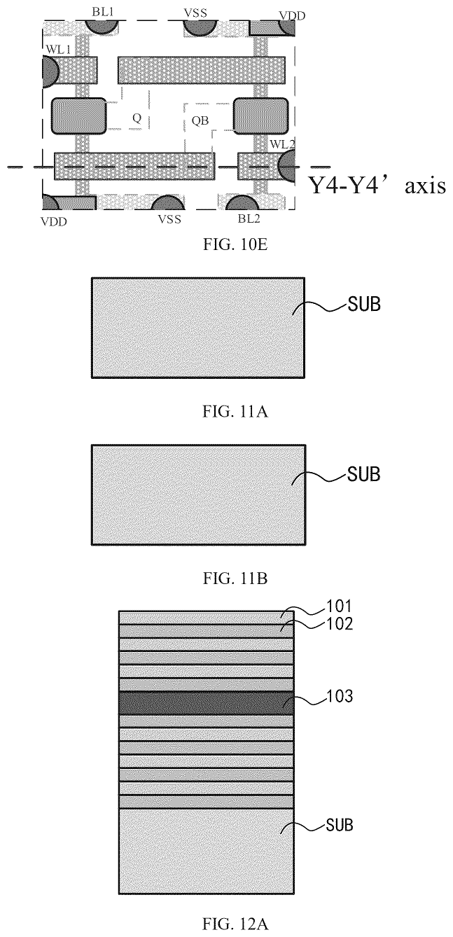

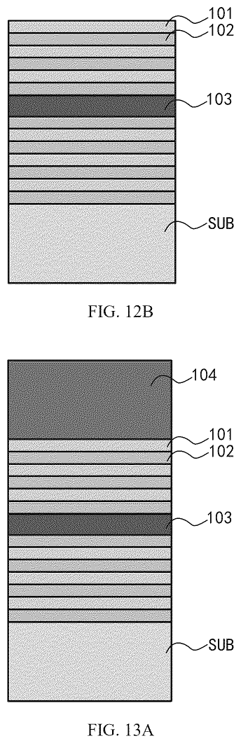

Specifically, taking a group of stacked field effect transistors as an example, FIG. 11A to FIG. 12A are cross-sectional views along the X-X′ axis in the process of manufacturing the vertically stacked semiconductor device. FIG. 11B to FIG. 12B are cross-sectional views along the Y4-Y4′ axis in the process of manufacturing the vertically stacked semiconductor device. Referring to FIG. 11A to FIG. 12A, and FIG. 11B to FIG. 12B, a material of the substrate SUB may include silicon, etc. Pretreatment operations, such as well lithography, ion implantation, annealing and cleaning, may be performed on the substrate SUB in sequence. After that, the lower stack, the intermediate layer 103 and the upper stack are sequentially arranged on the pretreated substrate SUB using an epitaxial growth process. Each of the lower stack and the upper stack includes channel layers 101 and sacrificial layers 102 that are alternatively arranged. Here, materials of the sacrificial layer 102 and the intermediate layer 103 may be the same, such as SiGe, Si, or the like. A material of the channel layer 101 may be doped silicon, etc. A channel layer 101 located above the intermediate layer 103 and a channel layer 101 located below the intermediate layer 103 may have the same doping element or different doping elements.

In a first embodiment of the present disclosure, the material of the channel layer 101 located above the intermediate layer 103 may be p-type doped silicon, and the material of the channel layer 101 located below the intermediate layer 103 may be n-type doped silicon. In a second embodiment of the present disclosure, the material of the channel layer 101 located above the intermediate layer 103 may be n-type doped silicon, and the material of the channel layer 101 located below the intermediate layer 103 may be p-type doped silicon. In a third embodiment of the present disclosure, the material of the channel layer 101 located above the intermediate layer 103 and the material of the channel layer 101 located below the intermediate layer 103 may be both n-type doped silicon, or both p-type doped silicon.

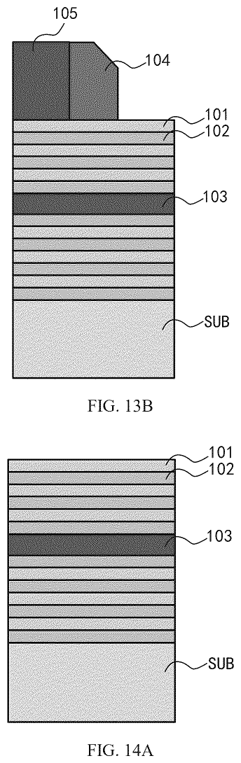

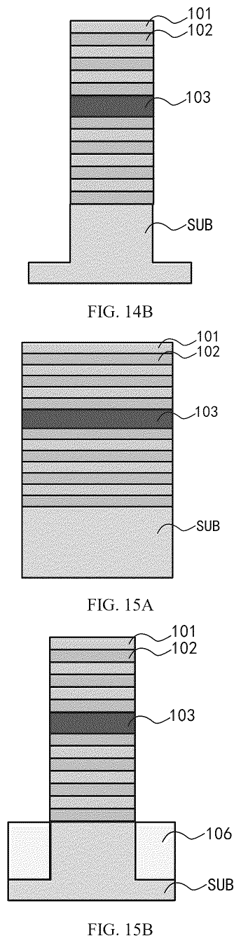

FIG. 13A to FIG. 15A are cross-sectional views along the X-X′ axis in the process of manufacturing the vertically stacked semiconductor device. FIG. 13B to FIG. 15B are cross-sectional views along the Y4-Y4′ axis in the process of manufacturing the vertically stacked semiconductor device. Refer to FIG. 13A to FIG. 15A, and FIG. 13B to FIG. 15B. A spacer 104 may be formed by a spacer image transfer (SIT) process. A material of the spacer 104 may be silicon nitride, etc. In the embodiments of the present disclosure, a mandrel 105 may be formed on the upper stack, and the mandrel 105 may be patterned using a photolithography process to obtain a linear pattern extending in the X direction. Here, a material of the mandrel 105 may be polycrystalline silicon, amorphous silicon, or the like. The spacer 104 is formed in the above region, and the patterned mandrel 105 is removed after the spacer 104 is formed, so that only the spacer 104 is left on the stack, thereby completing the manufacturing of the spacer 104. On this basis, the upper stack, the intermediate layer 103, the lower stack and the substrate SUB may be etched using an anisotropic etching process based on the pattern of the spacer 104, so as to form a fin on the substrate SUB and a substrate etching region distributed on opposite sides of the fin in the first direction. In the substrate etching region, a dielectric material 106 is deposited, and the dielectric material 106 is etched to a level either below or flush with an upper surface of a lower fin formed by the substrate SUB using an etch-back process, so that the dielectric material 106 serves as a shallow trench isolation member. The dielectric material in the embodiments of the present disclosure may include silicon dioxide, silicon nitride, or the like.

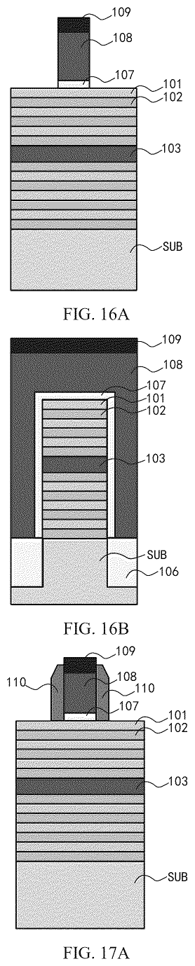

FIG. 16A to FIG. 20A are cross-sectional views along the X-X′ axis in the process of manufacturing the vertically stacked semiconductor device. FIG. 16B to FIG. 20B are cross-sectional views along the Y4-Y4′ axis in the process of manufacturing the vertically stacked semiconductor device. Referring to FIG. 16A to FIG. 20A, and FIG. 16B to FIG. 20B, a sacrificial gate spanning over the fin may be formed on the dielectric material 106 using processes such as thermal oxidation, chemical vapor deposition or sputtering. The sacrificial gate includes a gate oxide layer 107, a silicon layer 108 and a mask layer 109 from bottom to top, where a material of the gate oxide layer 107 may be SiO₂, etc. A material of the silicon layer 108 is amorphous silicon or polycrystalline silicon. A material of the hard mask layer 109 may be oxide, carbide, organic matter, or the like. On this basis, a gate spacer 110 may be formed on a sidewall of the sacrificial gate using a spacer formation process. A material of the gate spacer 110 may be SiCNO, etc. The upper stack, the intermediate layer and the lower stack may be etched based on the pattern of the sacrificial gate and the pattern of the gate spacer 110, thereby exposing the sidewall of the upper stack, the sidewall of the intermediate layer and the sidewall of the lower stack. The intermediate layer 103 and the sacrificial layer 102 may be set to have different etching selectivities, so that the intermediate layer 103 may be etched at a faster rate than the sacrificial layer 102. After the intermediate layer 103 is etched, an opening 112 is formed. An end of the sacrificial layer 102 in the first direction is recessed relative to the channel layer 101 to form an opening 111. Based on this, a space released within the fin due to the selective etching of the sacrificial layer 102 and the intermediate layer 103 is filled with a dielectric material. A portion of the dielectric material filled at the end of the sacrificial layer 102 serves as an inner spacer 113, and a portion of the dielectric material filled between the lower stack and the upper stack serves as an inter-device isolation layer 114. Thus, the inner spacer 113 and the inter-device isolation layer 114 are manufactured synchronously, so that the steps of the manufacturing process may be reduced. In addition, the inner spacer 113 of the first field effect transistor and the inner spacer 113 of the second field effect transistor manufactured using the above method have substantially aligned outer surfaces. Since an outer surface of the inner spacer 113 in the upper stack and an outer surface of the inner spacer 113 in the lower stack are substantially aligned with each other in the vertical direction, an area of the horizontal cross-section of the upper source/drain layer 119 is equal to an area of the horizontal cross-section of the lower source/drain layer 117 in the vertically stacked semiconductor device of the present disclosure, which may avoid an adverse outcome of misalignment of side edges of the upper and lower field effect transistors in the stacked field effect transistors in the vertical direction due to separately manufacturing the inner spacer 113 and the inter-device isolation layer 114.

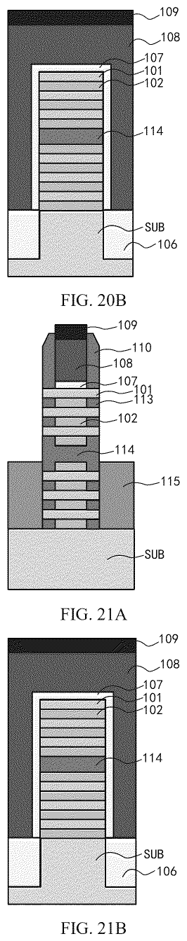

FIG. 21A to FIG. 27A are cross-sectional views along the X-X′ axis in the process of manufacturing the vertically stacked semiconductor device. FIG. 21B to FIG. 27B are cross-sectional views along the Y4-Y4′ axis in the process of manufacturing the vertically stacked semiconductor device. Referring to FIG. 21A to FIG. 27A and FIG. 21B to FIG. 27B, a lower source/drain position defining layer 115 in contact with a channel layer 101 is formed on opposite sides of the channel layer 101 below the inter-device isolation layer 114, and a spacer 116 is formed on the lower source/drain position defining layer 115 using a spacer forming process. Here, a material of the lower source/drain position defining layer 115 may include but is not limited to a-C (amorphous carbon). The formation method of the lower source/drain position defining layer 115 includes but is not limited to spin coating. For example, after depositing a-C, the deposited a-C may be planarized, and the a-C may be etched back to a level not higher than a middle position of the inter-device isolation layer 114. A material of the spacer 116 includes but is not limited to SiNₓ and the like. Here, the spacer 116 is used to protect the channel layer 101 located above the inter-device isolation layer, so as to prevent source/drain from growing at opposite ends of the channel layer 101 of the upper device during the growth process of the source/drain of the lower device. In the case of different types of the upper and lower devices, source/drain materials of the upper and lower devices may be different from each other.

After forming the spacer 116, the lower source/drain position defining layer 115 is removed to expose a sidewall of the channel layer 101 below the inter-device isolation layer 114. On the exposed sidewall of the channel layer 101, a source/drain material is epitaxially grown and in-situ doped, so as to form a source/drain layer 117 connected to the lower stack. Here, the source/drain material may be SiGe or Si. A dielectric material 118 may be deposited on the source/drain layer 117, and the dielectric material 118 may be etched to a level not higher than the inter-device isolation layer 114, so as to electrically isolate the source/drain layer of the upper device from the source/drain layer of the lower device. The spacer 116 may be selectively etched to expose a sidewall of the channel layer 101 above the inter-device isolation layer 114. On the exposed sidewall of the channel layer 101, a source/drain material is epitaxially grown and in-situ doped, so as to form a source/drain layer 119 connected to the upper stack. On this basis, the source/drain layer 117 and the source/drain layer 119 are activated to form the activated source/drain layer 117 and the activated source/drain layer 119.

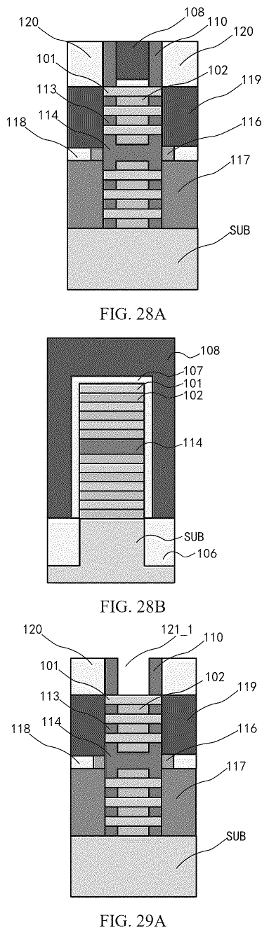

FIG. 28A to FIG. 37A are cross-sectional views along the X-X′ axis in the process of manufacturing the vertically stacked semiconductor device. FIG. 28B to FIG. 37B are cross-sectional views along the Y4-Y4′ axis in the process of manufacturing the vertically stacked semiconductor device. Referring to FIG. 28A to FIG. 37A and FIG. 28B to FIG. 37B, a dielectric material 120 is formed on the substrate SUB, and the dielectric material 120 is planarized. The planarization may remove the mask layer 109 in the sacrificial gate and expose the silicon layer 108. After that, the silicon layer 108 and the sacrificial layer 102 are etched using an etch-back process, so that on the inner side of the spacer 110 and the inner spacer 113, a cavity 121_1 exposed due to the etching is formed at the original position of the silicon layer 108, and a cavity 121_2 exposed due to the etching is formed at the original position of the sacrificial layer 102.

Gate stacks surrounding the channel layers 101 are sequentially formed on an inner sidewall of the cavity 121_1 and an inner sidewall of the cavity 121_2. The gate stack includes a gate dielectric layer 122 and a P-type work function layer 123. A material of the gate dielectric layer 122 may be a high-k dielectric material, where K represents a dielectric constant. The high-k dielectric material includes one of or a combination of HfO₂, HfSiOₓ, HfON, HfSiON, HfAlOₓ, HfLaOₓ, Al₂O₃, ZrO₂, ZrSiOₓ, Ta₂O₅ or La₂O₃. A material of the P-type work function layer 123 may be titanium nitride, etc. A protective layer 124 is formed on the substrate SUB, and the protective layer 124 is etched until a top surface thereof is located between the top surface and the bottom surface of the inter-device isolation layer 114 to cover the cavity for the lower layer device, so that the protective layer 124 protects the P-type work function layer 123 located in the cavity below the inter-device isolation layer 114 and exposes the P-type work function layer 123 located in the cavity above the inter-device isolation layer 114.

The P-type work function layer 123 above the inter-device isolation layer 114 is etched by using a selective etching process, and the gate dielectric layer 122 above the inter-device isolation layer 114 is retained. Then, an N-type work function layer 125 surrounding the gate dielectric layer 122 above the inter-device isolation layer 114 is formed. Thus, different gate stacks surrounding channel layers 101 are formed above and below the inter-device isolation layer 114, respectively. Thus, the channel layer 101, the gate stack and the source/drain layer 119 that are located above the inter-device isolation layer form an N-type field effect transistor; and the channel layer 101, the gate stack and the source/drain layer 117 that are located below the inter-device isolation layer form a P-type field effect transistor, thereby obtaining stacked field effect transistors.

It should be understood that the above is only an embodiment of the present disclosure. In the manufacturing process of other embodiments of the present disclosure, an N-type field effect transistor or a P-type field effect transistor may be formed as desired by changing a doping type of a source/drain layer and forming a corresponding type of work function layer. For example, the upper N-type field effect transistor may be formed as a P-type field effect transistor, and/or the lower P-type field effect transistor may be formed as an N-type field effect transistor.

After manufacturing the above-mentioned N-type field effect transistor and P-type field effect transistor, the protective layer 124 is removed to release a cavity below the inter-device isolation layer 114. After that, a conductive material is deposited in all the cavities 121_1 and all the cavities 121_2 to form a conductive layer 126, thereby completing the manufacturing of a gate structure. The conductive material in the embodiments of the present disclosure may include tungsten, etc. After the conductive layer 126 is formed, the conductive layer 126 may be planarized, and a dielectric material may be deposited on the planarized conductive layer 126. On this basis, a contact hole 127 connected to the source/drain layer 119 may be formed in the dielectric material 120.

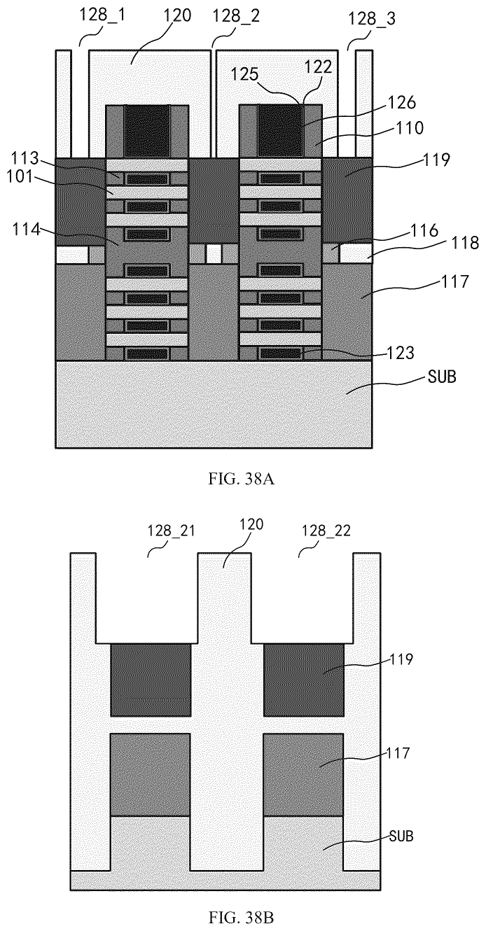

Specifically, taking the four field effect transistors in the first group of field effect transistors and the four field effect transistors in the second group of field effect transistors as an example, FIG. 38A to FIG. 41A are cross-sectional views along the X-X′ axis in the process of manufacturing the vertically stacked semiconductor device. FIG. 38B to FIG. 41B are cross-sectional views along the Y3-Y3′ axis in the process of manufacturing the vertically stacked semiconductor device. FIG. 41C is a cross-sectional view along the Y1-Y1′ axis in the process of manufacturing the vertically stacked semiconductor device. FIG. 41D is a cross-sectional view along the Y2-Y2′ axis in the process of manufacturing the vertically stacked semiconductor device.

On this basis, FIGS. 38A to 41A, FIGS. 38B to 41B, FIGS. 41C and 41D show cross-sectional schematic diagrams of a structure in which the above-mentioned eight field effect transistors are integrated. On an upper surface of the dielectric material 120, the dielectric material 120 is etched until the source/drain layer 119 is exposed, so as to form an opening 128_1, an opening 128_2, and an opening 128_3 that are located in the dielectric material 120. Here, the opening 128_2 includes an opening 128_21 corresponding to the first group of field effect transistors and an opening 128_22 corresponding to the second group of field effect transistors. On this basis, taking the opening 128_2 as an example, the opening 128_2 is further etched based on a position of the source/drain layer 117 which serves as a common layer, so that the opening 128_2 exposes both the source/drain layer 119 and the source/drain layer 117. The openings 128_1, 128_2 and 128_3 may be filled with a conductive material, thereby forming contact holes 127_1, 127_2 and 127_3 respectively. Here, the contact hole 127_2 includes a contact hole 127_21 formed by filling the opening 128_21 and a contact hole 127_22 formed by filling the opening 128_22. The contact hole 127_1 may be formed based on a similar manner. The contact hole 127_1 includes a contact hole 127_11 and a contact hole 127_12. A dielectric material is deposited on the contact hole 127_1, the contact hole 127_2 and the contact hole 127_3. It should be noted there is a structure above a right conductive layer 126 in FIG. 41D, which protrudes from an upper surface of the conductive layer 126. This structure is used as a connection line extending in a direction (corresponding to the first direction) perpendicular to the paper surface. In addition, a left conductive layer 126 in FIG. 41D extends to the left side so as to facilitate leading out a pad for connecting a word line terminal from the back side.

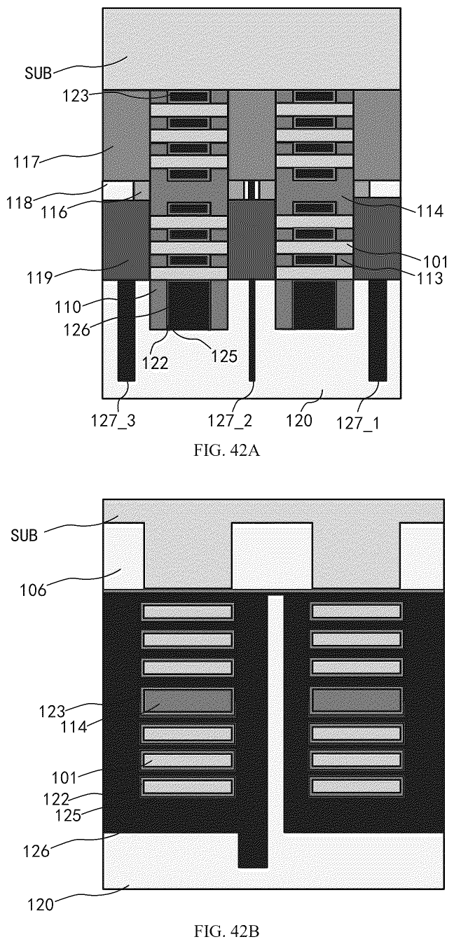

FIG. 42A to FIG. 45A are cross-sectional views along the X-X′ axis in the process of manufacturing the vertically stacked semiconductor device. FIG. 42B to FIG. 45B are cross-sectional views along the Y4-Y4′ axis in the process of manufacturing the vertically stacked semiconductor device. Refer to FIG. 42A to FIG. 45A, and FIG. 42B to FIG. 45B. It should be noted that in FIG. 42A to FIG. 45A, and FIG. 42B to FIG. 45B, the stacked field effect transistors are inverted for ease of description, and the same applies to the following other figures. It should be noted that hereinafter, the terms “above” and “below” are described based on the vertically stacked semiconductor device that is not inverted. After the field effect transistor is inverted, another substrate USUB may be bonded above the stacked field effect transistors, and a material of the substrate USUB is the same as that of the above-mentioned substrate SUB. In the embodiments of the present disclosure, the first group of field effect transistors and the second group of field effect transistors each include a lower fin formed by etching the substrate SUB. A remaining portion of the substrate after the etching is connected between the lower fin of the first group of field effect transistors and the lower fin of the second group of field effect transistors. An intermediate dielectric layer surrounding the first group of field effect transistors, the second group of field effect transistors and the substrate SUB is formed, which includes: etching part of the substrate from the bottom until a lower surface of the lower fin of the first group of field effect transistors and a lower surface of the lower fin of the second group of field effect transistors are exposed. A dielectric material 129 is deposited on each of the lower surface of the lower fin of the first group of field effect transistors and the lower surface of the lower fin of the second group of field effect transistors. Thus, the lower fin of the first group of field effect transistors and the lower fin of the second group of field effect transistors may be electrically isolated from each other.

Specifically, a fully silicided layer Fully Silicide may be formed on the exposed lower surface of the gate stack and the exposed lower surface of the source/drain layer in the lower field effect transistor. For example, the lower field effect transistor and the upper field effect transistor are inverted, so that the exposed lower surface of the gate stack and the exposed lower surface of the source/drain layer 117 in the lower field effect transistor face upward. A silicon layer is deposited on the exposed lower surface of the gate stack facing upward and the exposed lower surface of the source/drain layer 117 facing upward in the lower field effect transistor. A metal is used to perform a low-temperature silicidation reaction with the silicon layer, so as to form the fully silicided layer Full Silicide. For example, the metal includes at least one of Ti, Ni, Co, W, Pt, Al, Cu or Ru.

The fully silicided layer Fully Silicide is patterned to remove the fully silicided layer Fully Silicide at a lower surface of the lowest gate stack in the lower field effect transistor, so that the lower surface of the lowest gate stack in the lower field effect transistor does not contact the fully silicided layer Fully Silicide, thereby forming an opening that exposes the lower surface of the lowest gate stack in the lower field effect transistor; and at the same time, a silicided layer pattern FSP, which is connected to the lower surface of the source/drain layer 117 in the lower field effect transistor, is formed on opposite sides of the opening in the first direction. By filling the opening with a dielectric material, a lower isolation layer 129 may be formed. On this basis, the fully silicided layer Fully Silicide may be patterned. For example, the fully silicided layer Fully Silicide is etched in the second direction according to a width of the gate stack surrounding the channel layers 101 in the first direction, so as to form the opening and a silicide pattern arranged on opposite sides of the opening. The etching method here may include wet etching, dry etching, physical etching and the like. A length of the opening between the two silicided layer patterns FSP in the first direction is substantially equal to a length of the gate stack surrounding the channel layer 101 in the first direction, and the opening extends along the second direction. Thus, the opening may completely expose the lower surface of the lowest gate stack in the lower field effect transistor.

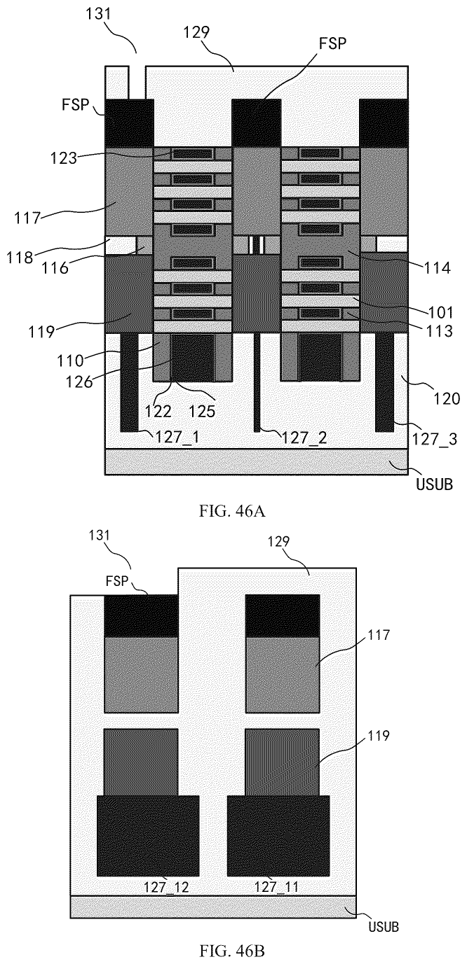

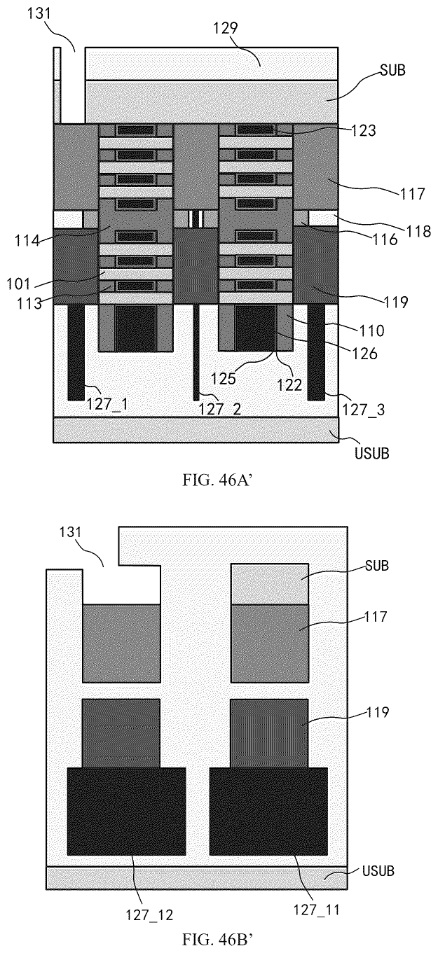

Continuing with the example of the four field effect transistors in the first group of field effect transistors and the four field effect transistors in the second group of field effect transistors, FIG. 46A to FIG. 49A are cross-sectional views along the X-X′ axis in the process of manufacturing the vertically stacked semiconductor device. FIG. 46B to FIG. 49B are cross-sectional views along the Y1-Y1′ axis in the process of manufacturing the vertically stacked semiconductor device. FIG. 48C is a cross-sectional view along the Y2-Y2′ axis in the process of manufacturing the vertically stacked semiconductor device. FIG. 48D is a cross-sectional view along the Y3-Y3′ axis in the process of manufacturing the vertically stacked semiconductor device. FIG. 49C is a cross-sectional view along the Y2-Y2′ axis in the process of manufacturing the vertically stacked semiconductor device. FIG. 49D is a cross-sectional view along the Y3-Y3′ axis in the process of manufacturing the vertically stacked semiconductor device.

Referring to FIG. 46A to FIG. 49A, FIG. 46B to FIG. 49B, FIG. 48C, FIG. 48D, FIG. 49C and FIG. 49D, the above method of manufacturing the semiconductor device further includes the following steps. A dielectric layer surrounding the lower field effect transistor and the upper field effect transistor is formed. The dielectric layer is etched from top to form a source/drain layer opening that exposes an upper surface of the source/drain layer 119 of the upper field effect transistor, where a projection of the source/drain layer opening in the vertical direction protrudes, in the second direction, from a projection of the source/drain layer of the upper field effect transistor in the vertical direction. The source/drain layer opening is filled with a conductive material, and the filled source/drain layer opening is sealed with a dielectric material, so as to form the contact holes 127_11 and 127_12. According to a portion where the projection of the source/drain layer opening protrudes from the projection of the source/drain layer of the upper field effect transistor, the dielectric layer is etched from bottom, so as to form openings 132_1 and 132_2 that expose a lower surface of the conductive material (i.e., the conductive material in the contact holes 127_11 and 127_12). The opening exposing the lower surface of the conductive material is filled with a conductive material, so as to form a contact hole connected to the source/drain layer 119 of the upper field effect transistor. The contact hole is used to electrically connect the source/drain layer 119 of the upper field effect transistor to a ground terminal. Alternatively, the contact hole is used to electrically connect the source/drain layer 119 of the upper field effect transistor to a bit line terminal. For example, one of the contact holes 133_1 and 133_2 may electrically connect the source/drain layer 119 of the upper field effect transistor to the ground terminal, and the other of the contact holes 133_1 and 133_2 may electrically connect the source/drain layer 119 of the upper field effect transistor to the bit line terminal.

Specifically, a dielectric material is deposited on a lower side of the substrate SUB, and a lithography process is performed on the dielectric material and the substrate SUB, so as to form an opening 131 exposing the lower surface of the silicided layer pattern FSP as well as openings 132_1 and 132_2 exposing the conductive material in contact with the upper source/drain layer. A conductive material is deposited into the above-mentioned openings 131, 132_1 and 132_2, so as to form a contact hole in the back of the device through the opening 131 which exposes the lower surface of the silicided layer pattern FSP, and to form an interlayer contact through hole in the back of the device through the openings 132_1 and 132_2 which expose the conductive material in contact with the upper source/drain layer 119. Here, the conductive material filled into the opening 131 forms a back contact hole (BSCON) 130 electrically connected to a power supply terminal. The conductive material filled into the opening 132_1 and the conductive material filled into the opening 132_2 respectively form a back interlayer contact through hole (BSVPR) 133_1 and a back interlayer contact through hole 133_2, which are respectively electrically connected to the ground terminal and the first bit line terminal. After depositing the conductive material, the conductive material exposed outside the dielectric material is planarized.

On this basis, a plurality of contact holes on the backside of the device may be formed using a back-end-of-line interconnect process. For example, the conductive material filled into the opening 134 is formed as a contact hole electrically connected to a second bit line terminal which is complementary to the first bit line terminal. In addition, the left conductive layer 126 in FIG. 49C is led out from the back of the device, so as to be electrically connected to a word line terminal WL on the back of the device. On this basis, referring to FIG. 46A′ to FIG. 49A′, FIG. 46B′ to FIG. 49B′, FIG. 48C′, FIG. 48D′, FIG. 49C′ and FIG. 49D′, it may be seen that in the vertically stacked semiconductor device in the related art, the substrate SUB is not completely etched away, and silicided layer patterns FSP as well as the dielectric in the lower isolation layer 129 located between the silicided layer patterns FSP are not formed, so that the substrate SUB will contact the lower surface of the lowest gate stack in the lower field effect transistor, resulting in creating a parasitic silicon channel on the back of the nanosheet channel and thus a leakage current.

Based on this, according to the method of manufacturing a vertically stacked semiconductor device in the present disclosure, the substrate SUB is etched, so that the lower surface of the lowest gate stack and the lower surface of the source/drain layer 117 in the lower field effect transistor are exposed, and then the fully silicided layer Fully Silicide covering the entire lower surface of the device is formed in a single process step on the exposed lower surface of the gate stack and the exposed lower surface of the source/drain layer 117 in the lower field effect transistor. Then, the fully silicided layer Fully Silicide is patterned, so that the fully silicided layer Fully Silicide at the lower surface of the lowest gate stack in the lower field effect transistor is removed, thereby forming an opening exposing the lower surface of the lowest gate stack in the lower field effect transistor and forming a silicided layer pattern FSP connected to the lower surface of the source/drain layer 117 in the lower field effect transistor on opposite sides of the opening in the first direction. In this way, the silicided layer pattern FSP connected to the source/drain layer 117 is formed in a self-aligned manner, which may avoid the lithography overlay tolerance. In addition, since the source/drain layer 117 in the lower field effect transistor is electrically connected to the contact hole 130 through the silicided layer pattern FSP, an area and a volume of the metal in contact with the source/drain may be expanded through the silicided layer pattern.

Moreover, by filling the opening between the silicided layer patterns FSP with the dielectric material to form the lower isolation layer 129, self-aligned dielectric isolation under the gate may be achieved, and the parasitic silicon channel on the back of the nanosheet channel due to the substrate SUB may be effectively removed, thereby avoiding an additional leakage current. Therefore, the method of manufacturing the vertically stacked semiconductor device in the present disclosure may feature a simplified manufacturing process, and the semiconductor device manufactured thereby may have good performance. It should be understood that in the embodiments of the present disclosure, the dielectric material includes but is not limited to SiO₂, SiNₓ, SiNO, SiCO, SiCNO, SiCN, polymer, a-C and other dielectrics and combinations. The dielectric filling method includes but is not limited to ALD (atomic layer deposition), CVD (chemical vapor deposition), Spin, etc. In addition, the etching method includes but is not limited to wet etching, RIE (reactive ion etching), RPS (remote plasma source) etching, chemical dry etching, ALE (atomic layer etching), etc. The present disclosure does not limit this, as long as the above-mentioned manufacturing method in the present disclosure may be implemented.

FIG. 50 schematically shows a schematic diagram of a vertically stacked semiconductor device according to an embodiment of the present disclosure.

As shown in FIG. 50, a vertically stacked semiconductor device 5000 in this embodiment includes: a lower field effect transistor 5001 and an upper field effect transistor 5002 stacked in the vertical direction; an inter-device isolation layer 114 between the lower field effect transistor 5001 and the upper field effect transistor 5002, where for example, since the inter-device isolation layer 114 and an adjacent inner spacer 113 are manufactured through a single step, the inter-device isolation layer 114 and the adjacent inner spacer 113 are formed as an integral structure in the vertically stacked semiconductor device of the embodiments of the present disclosure; and silicide patterns FSP and a lower isolation layer 129 that are alternately arranged on the lower surface of the lower field effect transistor 5001. Each of the lower field effect transistor 5001 and the upper field effect transistor 5002 includes: a plurality of channel layers 101 stacked with spacing between each other in the vertical direction; the source/drain layer 117 connected to the channel layers 101 on opposite sides of the plurality of channel layers 101 in the first direction; and a gate stack that extends in the second direction intersecting the first direction and surrounds the channel layers 101. The gate stack surrounding the channel layers 101 corresponds to the gate structure G in FIG. 50 (the channel layers 101 are surrounded by the gate structure G and is not shown in the perspective view of FIG. 50). The lower surface of the lowermost gate stack in the lower field effect transistor 5001 is covered by the lower isolation layer 129, the lower surface of the source/drain layer 117 of the lower field effect transistor 5001 is covered by the upper surface of the silicide pattern FSP, and the lower surface of the silicide pattern FSP is connected to the contact hole 130.

For example, the contact hole 130 connected to the lower surface of the silicide pattern FSP is electrically connected to a power supply terminal. A contact hole (corresponding to the above-mentioned contact holes 133_1 and 133_2) connected to the upper surface of the source/drain layer 119 of the upper field effect transistor 5002 extends downward from a side of the upper field effect transistor 5002, so as to be electrically connected to a bit line terminal or a ground terminal from a backside of the vertically stacked semiconductor device 5000. A thickness of the fully silicided layer is in a range of 5 nm to 500 nm.

According to the embodiments of the present disclosure, in the upper field effect transistor, the gate stack includes a portion on an upper surface of the uppermost channel layer 101 among the plurality of channel layers 101 in the upper field effect transistor, and in the lower field effect transistor, the gate stack includes a portion on a lower surface of the lowermost channel layer 101 among the plurality of channel layers 101 in the lower field effect transistor. As such, according to the manufacturing method of the present disclosure, the gate stack may surround the channel layer 101 in a more all-round manner, so that the performance of the manufactured semiconductor device may be improved.

According to the embodiments of the present disclosure, there are a plurality of sets of vertically stacked field effect transistors, each of which is composed of an upper field effect transistor and a lower field effect transistor, and two of the plurality of sets of vertically stacked field effect transistors form an inverter. In the vertically stacked semiconductor device, a plurality of inverters are cross-coupled with each other to form an SRAM structure.

According to the embodiments of the present disclosure, for the two sets of vertically stacked field effect transistors used to form the inverter, the two sets of vertically stacked field effect transistors share a same drain layer, and the shared drain layer is electrically connected to a signal output terminal. In two sets of vertically stacked field effect transistors, two source layers of one set of vertically stacked field effect transistors are electrically connected to the ground terminal, and two source layers of the other set of vertically stacked field effect transistors are respectively electrically connected to the bit line terminal and the power supply.

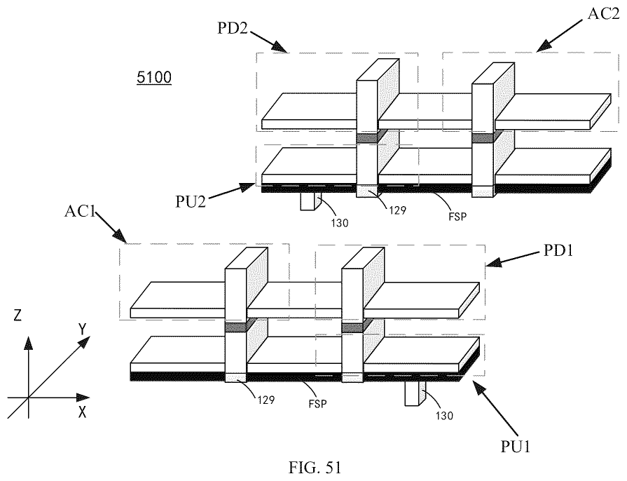

Specifically, the structure of the above-mentioned vertically stacked semiconductor device in the present disclosure is described below with FIG. 51 as an example. FIG. 51 schematically shows a schematic diagram of an SRAM structure implemented based on a vertically stacked semiconductor device according to an embodiment of the present disclosure. It should be noted that in FIG. 51, the extension direction of the X-axis is defined as the first direction, the extension direction of the Y-axis is defined as the second direction intersecting the first direction, and the extension direction of the Z-axis is defined as the vertical direction. In an embodiment of the present disclosure, the first direction and the second direction may be perpendicular to each other in a same horizontal plane. The vertical direction may be a direction perpendicular to the horizontal plane.

As shown in FIG. 51, the SRAM structure 5100 in this embodiment includes: a first set of field effect transistors and a second set of field effect transistors arranged on the upper surface of the substrate SUB in the first direction, and a dielectric layer surrounding the substrate SUB, the first set of field effect transistors and the second set of field effect transistors.

Each field effect transistor shown in FIG. 51 may be used as a transmission transistor, a pull transistor, or the like according to actual needs. Here, the transmission transistor may be a transistor for transmitting write data from a bit line. The pull transistors may include a pull-up transistor and a pull-down transistor. The pull-up transistor may be a transistor for pulling up a node level. The pull-down transistor may be a transistor for pulling down a node level. In addition, in FIG. 51, in order to avoid blocking the SRAM structure 5100, the dielectric layer is omitted from FIG. 51. It should be understood that the dielectric layer in the embodiments of the present disclosure may be arranged in the SRAM structure 5100 as desired.

With continued reference to FIG. 51, FIG. 51 shows two groups of field effect transistors arranged in the second direction. Each group of field effect transistors includes a plurality of field effect transistors integrated as an integral structure. Based on this, for ease of description, in the present disclosure, the plurality of field effect transistors located on the substrate SUB at the lower left of FIG. 51 are defined as a first group of field effect transistors, which are defined as being located in the front of the space shown in FIG. 51; and the transistors located on the substrate at the upper right of FIG. 51 are defined as a second group of field effect transistors, which are defined as being located in the rear of the space shown in FIG. 51.

Hereinafter, the field effect transistors shown in FIG. 51 are defined as pull transistors or transmission transistors, so as to facilitate the understanding of the SRAM structure 5100 in the embodiments of the present disclosure. It should be understood that the following is only an example, and the function of the field effect transistor in the SRAM structure 5100 may be set by those skilled in the art as desired.

For example, the transistor located at the upper left in the first group of field effect transistors is defined as a transmission transistor AC1; the transistor located at the upper right in the first group of field effect transistors is defined as a pull-down transistor PD1; and the transistor located at the lower right in the first group of field effect transistors is defined as a pull-up transistor PU1. It may be seen from FIG. 51 that the transmission transistor AC1 and the pull-down transistor PD1 are coupled to each other through a common layer. In addition, in the first group of field effect transistors, the common layer in the upper layer and the common layer in the lower layer are coupled to each other through a connection structure. Based on this, electrical connections between the transmission transistor AC1, the pull-up transistor PU1 and the pull-down transistor PD1 may be achieved. In addition, the common layers for electrical connections between the transmission transistor AC1, the pull-up transistor PU1 and the pull-down transistor PD1 respectively correspond to first source/drain layers of the transmission transistor AC1, the pull-up transistor PU1 and the pull-down transistor PD1. Here, the transmission transistor AC1 may be electrically connected to a bit line terminal through a source layer contact hole connected to a second source/drain layer located on the other side of the gate structure of the transmission transistor AC1, and the transmission transistor AC1 may be electrically connected to a word line terminal through a gate contact hole connected to the gate structure G of the transmission transistor AC1. The pull-up transistor PU1 may be electrically connected to a power supply terminal through a source layer contact hole connected to a second source/drain layer located on the other side of the gate structure of the pull-up transistor PU1, and the pull-down transistor PD1 may be electrically connected to a ground terminal through a source layer contact hole connected to a second source/drain layer located on the other side of the gate structure of the pull-down transistor PD1. Based on this, the stacked pull transistors in the first group of field effect transistors may form an inverter, the pull-up transistor PU1 may achieve a level of the pull-up common layer, and the pull-down transistor PD1 may achieve a level of the pull-down common layer.

Correspondingly, the transistor located at the upper right in the second group of field effect transistors is defined as a transmission transistor AC2; the transistor located at the lower left in the second group of field effect transistors is defined as a pull-down transistor PD2; and the transistor located at the upper left in the second group of field effect transistors is defined as a pull-up transistor PU2. It may be seen from FIG. 51 that the transmission transistor AC2 and the pull-down transistor PU2 are coupled with each other through a common layer. In addition, in the second group of field effect transistors, the common layer in the upper layer and the common layer in the lower layer are coupled to each other through a connection structure. Based on this, electrical connections between the transmission transistor AC2, the pull-up transistor PU2 and the pull-down transistor PD2 may be achieved. In addition, the common layers for the electrical connections between the transmission transistor AC2, the pull-up transistor PU2 and the pull-down transistor PD2 respectively correspond to first source/drain layers of the transmission transistor AC2, the pull-up transistor PU2 and the pull-down transistor PD2. Here, the transmission transistor AC2 may be electrically connected to a bit line terminal through a source layer contact hole connected to a second source/drain layer located on the other side of the gate structure of the transmission transistor AC2, and the transmission transistor AC2 may be electrically connected to a word line terminal through the gate contact hole connected to the gate structure G of the transmission transistor AC2. The pull-up transistor PU2 may be electrically connected to a power supply terminal through a source layer contact hole connected to a second source/drain layer located on the other side of the gate structure of the pull-up transistor PU2, and the pull-down transistor PD2 may be electrically connected to a ground terminal through a source layer contact hole connected to a second source/drain layer located on the other side of the gate structure of the pull-down transistor PD2. Based on this, the stacked pull transistors in the second group of field effect transistors may form an inverter, the pull-up transistor PU2 may achieve a level of the pull-up common layer, and the pull-down transistor PD2 may achieve a level of the pull-down common layer.

In the embodiments of the present disclosure, the gate structure of the pull-up transistor PU1 and the gate structure of the pull-down transistor PD1 may be electrically connected to the common layer in the second group of field effect transistors through a contact hole, so as to be electrically connected to a second data output terminal; the gate structure of the pull-up transistor PU2 and the gate structure of the pull-down transistor PD2 may be electrically connected to the common layer in the first group of field effect transistors through a contact hole, so as to be electrically connected to a first data output terminal. The gate structures of the transmission transistors AC1 and AC2 may be electrically connected to the word line terminal through contact holes, thereby achieving the SRAM structure of the present disclosure. The contact hole for the electrical connection between the gate structure and the common layer, and the contact hole for the electrical connection between the transmission transistor and the word line terminal may be manufactured using the above-mentioned back-end-of-line interconnect process, which will not be described in detail here.

Those skilled in the art may understand that the features described in the various embodiments of the present disclosure may be combined and/or integrated in various ways, even if such combinations or integrations are not explicitly described in the present disclosure. In particular, without departing from the spirit and teachings of the present disclosure, the features described in the various embodiments of the present disclosure may be combined and/or integrated in various ways. All these combinations and/or integrations fall within the scope of the present disclosure.

The embodiments of the present disclosure are described above. However, these embodiments are for illustrative purposes only and are not intended to limit the scope of the present disclosure. Although the embodiments are described above separately, this does not mean that the techniques in the various embodiments cannot be combined advantageously. Without departing from the scope of the present disclosure, those skilled in the art may make various substitutions and modifications, which should all fall within the scope of the present disclosure.

What is claimed is:

1. A method of manufacturing a semiconductor device, comprising:
arranging, on a substrate, a lower field effect transistor and an upper field effect transistor stacked in a vertical direction and an inter-device isolation layer between the lower field effect transistor and the upper field effect transistor, wherein each of the lower field effect transistor and the upper field effect transistor comprises: a plurality of channel layers stacked with spacing between each other in the vertical direction; a source/drain layer connected to the plurality of channel layers on opposite sides of the plurality of channel layers in a first direction; and a gate stack that extends in a second direction intersecting the first direction and surrounds the plurality of channel layers; and wherein an upper surface of the substrate is connected to a lower surface of a lowest gate stack and a lower surface of the source/drain layer in the lower field effect transistor;
etching the substrate to expose the lower surface of the lowest gate stack and the lower surface of the source/drain layer in the lower field effect transistor;
forming a fully silicided layer on the exposed lower surface of the lowest gate stack and the exposed lower surface of the source/drain layer in the lower field effect transistor;
patterning the fully silicided layer so that the fully silicided layer at the lower surface of the lowest gate stack in the lower field effect transistor is removed, so as to form an opening exposing the lower surface of the lowest gate stack in the lower field effect transistor, and to form a silicided layer pattern connected to the lower surface of the source/drain layer in the lower field effect transistor on opposite sides of the opening in the first direction simultaneously;
filling the opening with a dielectric material, so that the dielectric material filled in the opening serves as a lower isolation layer of the gate stack; and
arranging a contact hole connected to the silicided layer pattern.

2. The method according to claim 1, wherein the forming a fully silicided layer on the exposed lower surface of the lowest gate stack and the exposed lower surface of the source/drain layer in the lower field effect transistor comprises:
inverting the lower field effect transistor and the upper field effect transistor, so that the exposed lower surface of the lowest gate stack and the exposed lower surface of the source/drain layer in the lower field effect transistor face upward;
depositing a silicon layer on the exposed lower surface of the lowest gate stack and the exposed lower surface of the source/drain layer in the lower field effect transistor that face upward; and
forming the fully silicided layer by means of a silicide reaction of a metal with the silicon layer.

3. The method according to claim 2, wherein the metal comprises at least one of Ti, Ni, Co, W, Pt, Al, Cu or Ru.

4. The method according to claim 1, wherein the patterning the fully silicided layer comprises:
etching the fully silicided layer in the second direction according to a width of the gate stack surrounding the channel layers in the first direction, so as to form the opening and the silicided layer pattern arranged on the opposite sides of the opening.

5. The method according to claim 1, further comprising:
forming a dielectric layer surrounding the lower field effect transistor and the upper field effect transistor;
etching the dielectric layer from top to form a source/drain layer opening exposing an upper surface of the source/drain layer of the upper field effect transistor, wherein a projection of the source/drain layer opening in the vertical direction protrudes, in the second direction, from a projection of the source/drain layer of the upper field effect transistor in the vertical direction;
filling the source/drain layer opening with a conductive material;
sealing the filled source/drain layer opening with a dielectric material;
etching the dielectric layer from bottom according to a portion where the projection of the source/drain layer opening protrudes from the projection of the source/drain layer of the upper field effect transistor, so as to form an opening exposing a lower surface of the conductive material; and
filling the opening exposing the lower surface of the conductive material with a conductive material, so as to form a contact hole connected to the source/drain layer of the upper field effect transistor.

6. The method according to claim 5, wherein the contact hole is used to electrically connect the source/drain layer of the upper field effect transistor to a ground terminal; or the contact hole is used to electrically connect the source/drain layer of the upper field effect transistor to a bit line terminal.

7. The method according to claim 1, wherein the arranging, on a substrate, a lower field effect transistor and an upper field effect transistor stacked in a vertical direction and an inter-device isolation layer between the lower field effect transistor and the upper field effect transistor comprises:
sequentially arranging a lower stack, an intermediate layer and an upper stack on the substrate, wherein each of the upper stack and the lower stack comprises channel layers and sacrificial layers that are alternately arranged;
patterning the lower stack, the intermediate layer, the upper stack and an upper portion of the substrate, so as to form a fin extending in the first direction;
forming a sacrificial gate extending in the second direction and intersecting with the fin on the substrate;
forming a gate spacer on a sidewall of the sacrificial gate;
patterning the lower stack, the intermediate layer and the upper stack with the sacrificial gate and the gate spacer used as masks, so that each of the patterned lower stack, the patterned intermediate layer and the patterned upper stack comprises a side surface exposed in the first direction;
replacing the intermediate layer with the inter-device isolation layer;
forming the source/drain layer of the lower field effect transistor connected to an exposed side surface of the channel layers in the lower stack, and forming the source/drain layer of the upper field effect transistor connected to an exposed side surface of the channel layers in the upper stack; and
replacing the sacrificial gate and the sacrificial layers with the gate stack.

8. A vertically stacked semiconductor device, comprising:
a lower field effect transistor and an upper field effect transistor stacked in a vertical direction; an inter-device isolation layer between the lower field effect transistor and the upper field effect transistor; and fully silicided layers and a lower isolation layer that are alternately arranged on a lower surface of the lower field effect transistor,
wherein each of the lower field effect transistor and the upper field effect transistor comprises:
a plurality of channel layers stacked with spacing between each other in the vertical direction;
a source/drain layer connected to the plurality of channel layers on opposite sides of the plurality of channel layers in a first direction; and
a gate stack that extends in a second direction intersecting the first direction and surrounds the plurality of channel layers;
wherein a lower surface of a lowest gate stack in the lower field effect transistor is covered by the lower isolation layer; and
wherein a lower surface of the source/drain layer of the lower field effect transistor is covered by an upper surface of a silicide pattern, and a lower surface of the silicide pattern is connected to a contact hole.

9. The vertically stacked semiconductor device according to claim 8, wherein the contact hole connected to the lower surface of the silicide pattern is electrically connected to a power supply terminal; and
wherein a contact hole connected to an upper surface of the source/drain layer of the upper field effect transistor extends downward from a side of the upper field effect transistor, so as to be electrically connected to a bit line terminal or a ground terminal from a backside of the vertically stacked semiconductor device.

10. The vertically stacked semiconductor device according to claim 8, wherein a thickness of the silicide pattern is in a range of 5 nm to 500 nm.
